(19) United States
(12) Patent Application Publication
(10) Pub. No.: US 2024/0258386 A1
(43) Pub. Date: Aug. 1, 2024

(54) SEMICONDUCTOR APPARATUS, METHOD OF MANUFACTURING SEMICONDUCTOR APPARATUS, AND ELECTRONIC DEVICE INCLUDING SEMICONDUCTOR APPARATUS

(71) Applicant: Institute of Microelectronics, Chinese Aacademy of Sciences, Beijing (CN)

(72) Inventor: Huilong Zhu, Poughkeepsie, NY (US)

(21) Appl. No.: 18/289,998

(22) PCT Filed: Apr. 20, 2022
(86) PCT No.: PCT/CN2022/087854

§ 371 Date: Nov. 8, 2023

(30) Foreign Application Priority Data
Jun. 2, 2021 (CN) 202110616618.0

(51) Int. Cl. H01L 29/417; H01L 29/06; H01L 29/423; H01L 29/66; H01L 29/775; H01L 29/786

(52) U.S. Cl. CPC H01L 29/41733; H01L 29/0673; H01L 29/42392; H01L 29/66439; H01L 29/66545; H01L 29/775; H01L 29/78696

(57) ABSTRACT

Disclosed are a semiconductor apparatus, a manufacturing method, and an electronic device. The semiconductor apparatus includes first and second devices vertically stacked. Each of the first and second devices includes a first source/drain layer, a channel layer and a second source/drain layer vertically stacked, and a gate stack surrounding a periphery of the channel layer. The first device protrudes in a first direction relative to the second device to form a first step. A second step is defined by the second device. On a side in a second direction intersecting with the first direction, the first source/drain layer of each device protrudes in the second direction relative to the second source/drain layer and gate stack, to form a sub-step. Each sub-step is on a corresponding step. On another side in the second direction, the gate stack of each device protrudes in the second direction relative to the second source/drain layer.

### CROSS REFERENCE TO RELATED APPLICATION(S)

This application claims priority to Chinese Patent Application No. 202110616618.0, filed on Jun. 2, 2021 and entitled “SEMICONDUCTOR APPARATUS, METHOD OF MANUFACTURING SEMICONDUCTOR APPARATUS, AND ELECTRONIC DEVICE INCLUDING SEMICONDUCTOR APPARATUS”, the entire content of which is incorporated herein in its entirety by reference.

### TECHNICAL FIELD

The present disclosure relates to a field of semiconductors, in particular to a semiconductor apparatus with vertically stacked devices of different widths, a method of manufacturing the semiconductor apparatus, and an electronic device including the semiconductor apparatus.

### BACKGROUND

In a planar device such as a Metal Oxide Semiconductor Field Effect Transistor (MOSFET), a source, a gate and a drain are arranged in a direction substantially parallel to a substrate surface. Due to such an arrangement, the planar device is difficult to be further scaled down. In contrast, in a vertical device, a source, a gate and a drain are arranged in a direction substantially perpendicular to a substrate surface. As a result, the vertical device is easier to be scaled down compared to the planar device. Vertical devices may be stacked to increase the integration density.

### SUMMARY

In view of above, the object of the present disclosure is at least partially to provide a semiconductor apparatus in which devices with different widths are vertically stacked, a method of manufacturing the semiconductor apparatus, and an electronic device including the semiconductor apparatus.

According to an aspect of the present disclosure, a semiconductor apparatus is provided, including: a substrate; a first semiconductor device and a second semiconductor device which are stacked on the substrate in a vertical direction, and each of the first semiconductor device and the second semiconductor device includes a first source/drain layer, a channel layer and a second source/drain layer which are stacked in sequence in the vertical direction, and a gate stack surrounding a periphery of the channel layer. An end of the first source/drain layer, second source/drain layer and gate stack of the first semiconductor device in a first direction protrudes in the first direction relative to a corresponding end of the first source/drain layer, second source/drain layer and gate stack of the second semiconductor device in the first direction, so as to form a first step. A second step is defined by the second semiconductor device. An end of respective first source/drain layer of the first semiconductor device and the second semiconductor device in a second direction intersecting with the first direction protrudes in the second direction relative to a corresponding end of respective second source/drain layer and gate stack of the first semiconductor device and the second semiconductor device in the second direction, so as to respectively form a first sub-step and a second sub-step, wherein the first sub-step is on the first step, and the second sub-step is on the second step. In each of the first semiconductor device and the second semiconductor device, another end of the gate stack in the second direction, which is opposite to the end of the gate stack in the second direction, protrudes in the second direction relative to another end of the second source/drain layer in the second direction, which is opposite to the end of the second source/drain layer in the second direction.

According to another aspect of the present disclosure, a method of manufacturing a semiconductor apparatus is provided, including: disposing a stack including n device layers on a substrate, where each device layer includes a first source/drain layer, a channel defining layer and a second source/drain layer which are stacked in sequence, and n is an integer greater than or equal to 2; forming a step structure on a side of the stack in a first direction: a step is formed by a lower device layer relative to an upper device layer; recessing, on two opposite sides in the first direction, the channel defining layer in each device layer in the first direction relative to the first source/drain layer and second source/drain layer in each device layer, so as to obtain a first gap, and forming a first sacrificial gate in the first gap; recessing, on a side of the stack in a second direction intersecting with the first direction, the channel defining layer in each device layer in the second direction relative to the first source/drain layer and second source/drain layer in each device layer, so as to obtain a second gap; forming a channel layer on a sidewall of a recess of each channel defining layer; forming a second sacrificial gate in a space of the second gap after forming the channel layer; forming, on the side of the stack in the second direction, a step structure in each device layer: a sub-step is formed by each second sacrificial gate relative to the second source/drain layer in a corresponding device layer; removing, on another side of the stack opposite to the side of the stack in the second direction, the channel defining layer by selectively etching, so as to obtain a third gap, and forming a third sacrificial gate in the third gap; forming, on the another side of the stack in the second direction, a step structure in each device layer: a sub-step is formed by the first source/drain layer relative to the second source/drain layer and channel defining layer in a same device layer, and the sub-step is on the step formed in the corresponding device layer; and replacing the first sacrificial gate, the second sacrificial gate and the third sacrificial gate by a gate stack.

According to another aspect of the present disclosure, an electronic device is provided, including the aforementioned semiconductor apparatus.

According to embodiments of the present disclosure, devices with different widths may be vertically stacked, and components in a lower device such as a source/drain region and a gate stack, which require to be electrically connected, may protrude relative to an upper device, so as to facilitate electrical connection. As a result, a large integration density may be achieved.

### BRIEF DESCRIPTION OF THE DRAWINGS

The above and other objects, features, and advantages of the present disclosure will become more apparent through following description on embodiments of the present disclosure with reference to accompanying drawings, in which:

FIGS. 1 to 32(d) show schematic diagrams of some stages in a process of manufacturing a semiconductor apparatus according to an embodiment of the present disclosure;

FIG. 33 shows a local top view of an arrangement of a contact portion in a semiconductor apparatus according to another embodiment of the present disclosure;

FIG. 34 shows a schematic perspective view of a semiconductor apparatus according to another embodiment of the present disclosure;

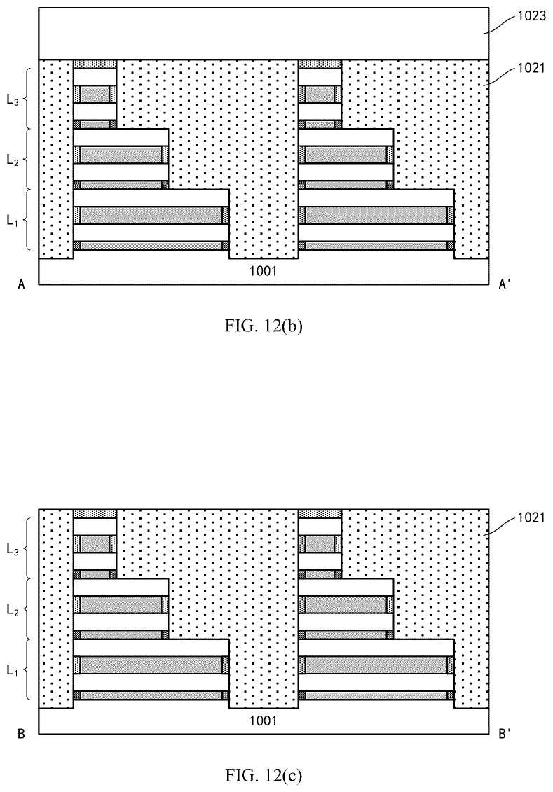

wherein FIGS. 12(a), 16(a), 24(a), 26(a), 27(a), 28 and 32(a) are top views, and FIG. 12(a) shows positions of line AA′, line BB′, line CC′ and line DD′,

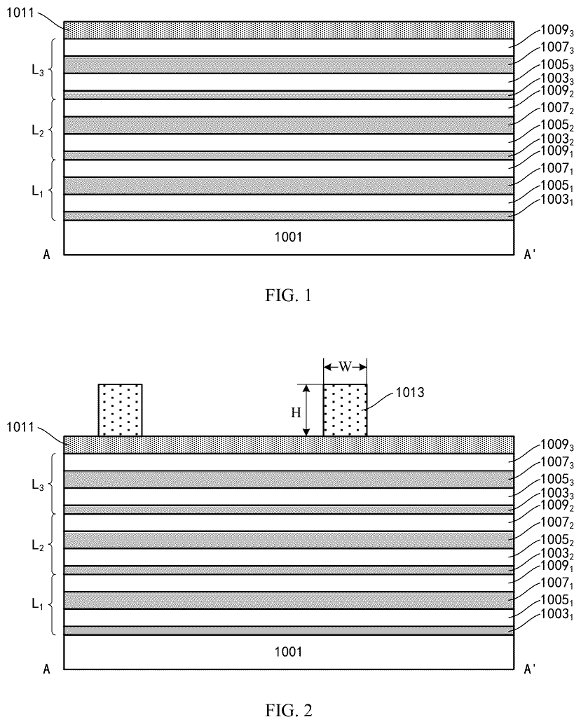

FIGS. 1 to 11, 12(b), 14(a), 15(a), 16(b), 23, 24(b), 25(a), 26(b), 27(b), 29(a), 30(a), 31(a) and 32(b) are cross-sectional views taken along line AA′,

FIGS. 12(c), 13, 14(b) and 15(b) are cross-sectional views taken along line BB′,

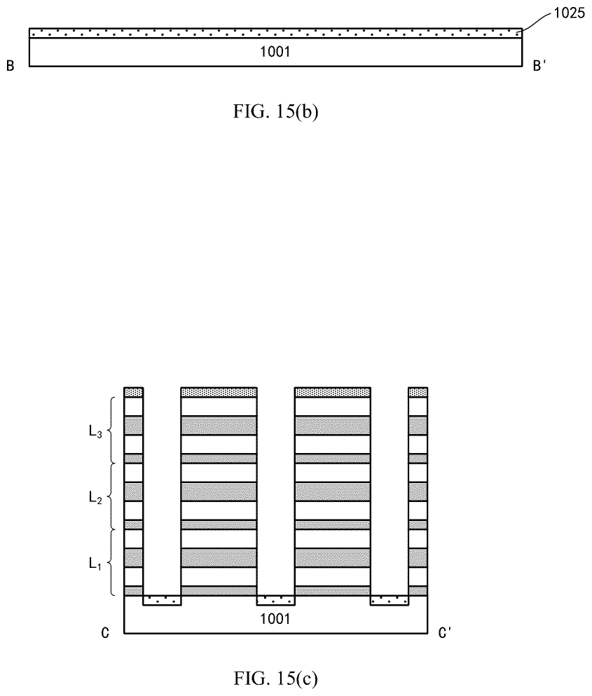

FIGS. 15(c), 16(c), 17 to 21, 22(a), 24(c), 25(b), 26(c), 27(c), 29(b), 30(b), 31(b) and 32(c) are cross-sectional views taken along line CC′,

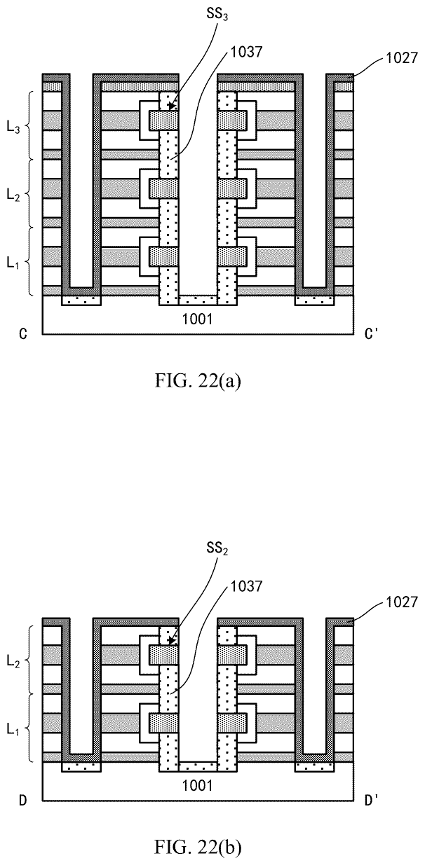

FIGS. 22(b), 24(d), 25(c), 26(d), 27(d), 29(c), 31(c) and 32(d) are cross-sectional views taken along line DD′.

Throughout the accompanying drawings, the same or similar reference numbers denote the same or similar components.

### DETAILED DESCRIPTION OF EMBODIMENTS

Hereinafter, embodiments of the present disclosure will be described with reference to accompanying drawings. However, it is to be understood that these descriptions are illustrative and not intended to limit the present disclosure. Further, in the following, known structures and technologies are not described to avoid obscuring the present disclosure unnecessarily.

In the accompanying drawings, various structures according to the embodiments of the present disclosure are schematically shown. However, they are not drawn to scale, and some features may be enlarged while some features may be omitted for sake of clarity. Moreover, shapes, relative sizes and positions of regions and layers shown in the drawings are also illustrative, and deviations may occur due to manufacture tolerances and technique limitations in practice. Those skilled in the art may also devise regions/layers of other different shapes, sizes, and relative positions as desired in practice.

In the context of the present disclosure, when a layer/element is recited as being “on” a further layer/element, the layer/element may be disposed directly on the further layer/element, or otherwise there may be an intervening layer/element interposed therebetween. Further, if a layer/element is “on” a further layer/element in an orientation, then the layer/element may be “under” the further layer/element when the orientation is turned.

According to embodiments of the present disclosure, a semiconductor apparatus including vertical semiconductor devices stacked on each other is provided. The vertical semiconductor device includes an active region extending vertically (for example, substantially perpendicular to a surface of a substrate) relative to a substrate. The active region may include a first source/drain layer, a channel layer and a second source/drain layer which are stacked in sequence. A source/drain region may be (at least partially) formed in the first source/drain layer and the second source/drain layer, and a channel region may be formed in the channel layer. A conductive channel may be formed between the source/drain regions located at two ends of the channel region through the channel region. A gate stack may be formed surrounding a periphery of the channel layer. Respective layers may be adjacent to each other, and of course there may be other semiconductor layers therebetween, such as a leaking suppression layer and/or an on-state current enhancement layer (a semiconductor layer with a band gap greater or less than an adjacent layer). These layers may be formed by epitaxial growth and may be single crystals.

For stacked devices, components (such as the first source/drain layer, the second source/drain layer and the gate stack) in a lower device that require to be electrically connected may protrude in a transverse direction relative to an upper device, so as to manufacture corresponding contact portions. For example, one end of the first source/drain layer, second source/drain layer and gate stack of the lower device in a first direction may protrude in the first direction relative to a corresponding end of the first source/drain layer, second source/drain layer and gate stack of the upper device in the first direction. A step is formed by a protruded portion. Respective contact portions to the first source/drain layer, second source/drain layer and gate stack of the lower device may be disposed on this step. An uppermost device may also be regarded as one “step”.

In addition, for the same device, the lower first source/drain layer may protrude in the transverse direction relative to the upper second source/drain layer and gate stack, and the lower gate stack may protrude in the transverse direction relative to the upper second source/drain layer, so as to manufacture a corresponding contact portion. For example, one end of the first source/drain layer of the same device in a second direction intersecting (such as perpendicular to) the first direction may protrude in the second direction relative to a corresponding end of the second source/drain layer and gate stack in the second direction. A sub-step is formed by the protruded portion. A contact portion to the first source/drain layer may be disposed on this sub-step. In addition, the other end of the gate stack of the same device in the second direction may protrude in the second direction relative to the other end of the second source/drain layer in the second direction. A sub-step is formed by the protruded portion. A contact portion to the gate stack may be disposed on this sub-step.

That is, a step structure (including respective steps) in the first direction may be formed between respective devices, and a step structure (including respective sub-steps) in the second direction may be formed between different layers of respective device itself. Each step may extend in the second direction, and each sub-step may be disposed on a step (more specifically, at two opposite ends of each step in the second direction) of a corresponding device. Each step in the step structure in the first direction ensures that at least a part of components in each device that require to be electrically connected are not shielded above them by components in other devices that require to be electrically connected. Each sub-step in the step structure in the second direction ensures that components in each device that require to be electrically connected are not shielded above them by other components in the each device that require to be electrically connected.

Due to such step structure, a width of each device, especially a width (which may define a gate width) of a channel layer of the device in the first direction, may vary. More specifically, a width of the lower device in the first direction may be greater than a width of the upper device in the first direction, and thus it is possible to have a greater driving current and a higher performance. As the number of stacked devices is increased, the width of the lower device may also be increased, thereby improving the performance without reducing an integration density.

The channel layer may have a form of a nanosheet extending in the first direction. The gate width may be defined by the width of the channel layer in the first direction as described above. A gate length may be defined by a height of the channel layer in a vertical direction. A thickness of the nanosheet may be defined by a thickness of the channel layer in the second direction.

For example, such semiconductor apparatus may be manufactured as follows.

A stack including of two or more device layers may be disposed on the substrate. Each device layer may be used to define a corresponding device, such as including the first source/drain layer, the channel defining layer and the second source/drain layer which are stacked in sequence. In addition, for the purpose of isolation between devices, at least some device layers may further include an isolation defining layer. The isolation defining layer may be replaced by an isolation material in a subsequent process.

A step structure may be formed on one side of the stack in the first direction, so that the lower device layer protrudes in the first direction relative to the upper device layer, so as to form a step. For example, the step structure may be formed by combining photoresist trimming with successive etching.

In addition, the channel defining layer may be relatively recessed on two opposite sides in the first direction, so as to form a gap. A first sacrificial gate may be formed in the gap. It is helpful to form a Gate-All-Around (GAA) configuration subsequently. In a case that the isolation defining layer does not have an etching selectivity relative to the channel defining layer or has a relatively low etching selectivity relative to the channel defining layer, the isolation defining layer may also be relatively recessed. In order to avoid the formation of the first sacrificial gate in such recess of the isolation defining layer, a plug may be formed in such recess first.

In the second direction intersecting (for example, perpendicular to) the first direction, on one side (which may be referred to as “first side”), a sacrificial gate (defining a position of the gate stack) for each device layer may relatively protrude to form a sub-step. On the other side (which may be referred to as “second side”), the first source/drain layer in each device layer may relatively protrude to form a sub-step. Accordingly, in the second direction, the first side and the second side may be performed separately. When one of the first side and the second side is processed, the other one of the first side and the second side may be shielded by a shielding layer.

For example, when the first side is processed, the channel defining layer may be relatively recessed by selectively etching, so as to obtain a gap. In this gap, a channel layer may be formed by, for example, epitaxial growth. Accordingly, the channel layer may be a nanosheet extending along the first direction. In a space left after growing the nanosheet in this gap, a second sacrificial gate may be formed. The second source/drain layer may be relatively recessed by selectively etching, so that a sub-step may be formed by each second sacrificial gate relative to a corresponding second source/drain layer. In a case that the first source/drain layer does not have an etching selectivity relative to the second source/drain layer (the first source/drain layer and the second source/drain layer are usually of the same material), the first source/drain layer may also be relatively recessed. The relative recess of the first source/drain layer and the second source/drain layer may be filled with a dielectric. The dielectric filled in this way may on the one hand define a gate space in a subsequent replacement gate process, and on the other hand prevent the first side from being affected when the second side is processed.

When the second side is processed, the channel defining layer may be removed by selectively etching, so as to obtain a gap. A third sacrificial gate is formed in the gap. Accordingly, the channel layer may be surrounded by the first sacrificial gate (on two opposite sides in the first direction), the second sacrificial gate (on the first side in the second direction), and the third sacrificial gate (on the second side in the second direction). A layer above the first source/drain layer may be removed by selectively etching in a certain region (such as an end portion region) of an exposed portion (that is, each step) of each device layer, so as to form a sub-step by relatively protruding the first source/drain layer in each device layer.

The present disclosure may be presented in various forms, and some examples of which will be described below. In the following description, the selection of various materials is involved. In selecting the materials, etching selectivity is considered in addition to the function of the material (for example, a semiconductor material is used to form the active region, a dielectric material is used to form an electrical isolation, and a conductive material is used to form an electrode, an interconnection structure, etc.). In the following description, the required etching selectivity may or may not be indicated. It should be clear to those skilled in the art that when etching a certain material layer is mentioned below, if it is not mentioned that other layers are also etched or the drawing does not show that other layers are also etched, then this etching may be selective, and the material layer may have etching selectivity with respect to other layers exposed to a same etching recipe.

FIGS. 1 to 32(d) show schematic diagrams of some stages in a process of manufacturing a semiconductor apparatus according to an embodiment of the present disclosure.

As shown in FIG. 1, a substrate 1001 is provided. The substrate 1001 may be various forms of substrates, including but not limited to a bulk semiconductor material substrate such as a bulk Si substrate, a semiconductor on insulator (SOI) substrate, a compound semiconductor substrate such as SiGe substrate, etc. In the following description, for the convenience of explanation, the bulk Si substrate such as a Si wafer is taken as an example for description.

On the substrate 1001, a first device layer L₁, a second device layer L₂ and a third device layer L₃ may be formed, for example, by epitaxial growth. An active region of the device may be defined from each device layer L₁, L₂, and L₃. For example, the first device layer L₁ may include a first source/drain layer 1005₁, a channel defining layer 1007₁ and a second source/drain layer 1009₁. Similarly, the second device layer L₂ may include a first source/drain layer 1005₂, a channel defining layer 1007₂ and a second source/drain layer 1009₂. The third device layer L₃ may include a first source/drain layer 1005₃, a channel defining layer 1007₃ and a second source/drain layer 1009₃. In addition, for the purpose of subsequent manufacturing electrical isolation, the device layers L₁, L₂ and L₃ may respectively include isolation defining layers 1003₁, 1003₂ and 1003₃. These semiconductor layers may have good crystal quality and may be single crystal structures. There may be a clear crystal interface between adjacent semiconductor layers.

It is noted that the isolation defining layer is disposed between every two adjacent device layers herein. However, the present disclosure is not limited thereto. For example, according to a circuit design, certain adjacent device layers may be electrically connected to each other, so that the isolation defining layer may not be disposed between them.

These semiconductor layers may include various suitable semiconductor materials, such as an elemental semiconductor material such as a IV group element semiconductor material such as Si or Ge, a compound semiconductor material such as a IV group compound semiconductor material such as SiGe, or a III-V group compound semiconductor material such as InP or GaAs. The material of the semiconductor layer may be selected based on factors such as properties of the substrate and device performance to be achieved.

In this embodiment, each semiconductor layer formed on the Si wafer may be Si-based materials. In addition, considering subsequent processes, adjacent semiconductor layers may have etching selectivity relative to each other. For example, each source/drain layer may include Si, and each channel defining layer and isolation defining layer may include SiGe (for example, an atomic ratio of Ge may be about 10% to 30%, preferably about 15%).

The semiconductor layer in each device layer may be appropriately doped according to a conductivity type of the device to be formed. For example, the first source/drain layer and the second source/drain layer may be heavily doped (for example, a doping concentration is about 1E18 cm⁻³ to 1E21 cm⁻³) to be of a same conductivity type as the device to be implemented, while the channel defining layer may be unintentionally doped or lightly doped to be of an opposite conductivity type as the device to be implemented, so as to adjust a threshold voltage of the device. Alternatively, for a tunneling device, the first source/drain layer and the second source/drain layer in the same device layer may be doped as opposite conductivity types. The doping of the semiconductor layer may be achieved by in-situ doping during epitaxial growth, or by other doping methods such as ion implantation. There may be a doping concentration interface between adjacent semiconductor layers.

Each semiconductor layer may have a suitable thickness (in the vertical direction). For example, the first source/drain layer and the second source/drain layer may have a thickness of about 20 nm to 50 nm. The isolation defining layer may have a thickness of about 10 nm to 20 nm. The channel defining layer may have a thickness of about 15 nm to 100 nm. Considering the subsequent processes, the thickness of each channel defining layer may be greater than the thickness of each isolation defining layer. In addition, at least some device layers may have different scales, so as to achieve different electrical characteristics. For example, thicknesses of the channel defining layers in at least some device layers may be different (to achieve different gate lengths) from each other. In addition, thicknesses of source/drain layers in at least some device layers may also be different from each other. For example, the thickness of the source/drain layer in the upper device layer may be less than the thickness of the source/drain layer in the lower device layer. Accordingly, the device formed subsequently in the lower device layer may have a relatively small resistance or a relatively large conduction current.

In addition, a hard mask layer 1011 may be formed above the semiconductor layer, so as to assist patterning. For example, the hard mask layer 1011 may include a nitride (such as a silicon nitride) with a thickness of about 50 nm to 200 nm.

In FIG. 1, three device layers L₁, L₂ and L₃ are shown, and a three-layer device may be formed subsequently. However, the present disclosure is not limited thereto. More or fewer device layers may be disposed and devices with corresponding layers may be formed.

The active region of the device may be patterned from the aforementioned semiconductor layer.

For example, a groove extending along the first direction (such as the horizontal direction within a paper plane in FIG. 1) and the second direction (such as a direction perpendicular to the paper plane in FIG. 1) intersecting with the first direction may be formed. The groove may be filled with a dielectric to form an isolation such as a shallow groove isolation (STI), so as to define an active region surrounded by such isolation.

Here, since a plurality of device layers are stacked, a step structure may be formed in the active region in order to facilitate connection to each device layer. Specifically, an active region of the lower device layer may protrude in the transverse direction relative to an active region of the upper device layer, so as to form a step. There are various ways in the art to form such step structure. For example, photoresist trimming combined with successive etching may be used to pattern the step structure. Each device layer L₁, L₂ and L₃ may be regarded as “one layer” when patterning, so that steps may be formed respectively between the first device layer L₁ and the second device layer L₂, and between the second device layer L₂ and the third device layer L₃.

In addition, such step structure may be formed only on one side or multiple sides of the active region, but not on other one side or other multiple sides of the active region (that is, on the other one side or the other multiple sides, the active regions in different device layers may be substantially aligned in the vertical direction), so as to save area. In order to define the other one side or the other multiple sides of the active region that do not require the formation of the step structure, as shown in FIG. 2, a cushion layer 1013 may be formed on a hard mask layer 1011. During subsequent photoresist trimming, the cushion layer 1013 may remain substantially unaffected, and thus maintain an edge of the active region defined by the cushion layer 1013 substantially aligned in the vertical direction (i.e., without forming a step structure). The cushion layer 1013 may include a material having an etching selectivity relative to the hard mask layer 1011, such as oxide (such as silicon oxide).

The cushion layer 1013 may be patterned as linear patterns (only two of them are shown in the figure, as an example) that are separated from each other in the first direction and extending along the second direction, so as to respectively define active regions of individual devices in each device layer (in combination with the photoresist described below). A sum of a height H of each pattern of the cushion layer 1013 in the vertical direction and a width W of each pattern of the cushion layer 1013 in the first direction may be greater than a difference between a width W₁ of an individual device to be defined in the first device layer L₁ as a lowest device layer and a width Wₙ₋₁ of an individual device to be defined in a second device layer from top to bottom, that is, (H+W)>(W₁−Wₙ₋₁), where n represents a total number of device layers formed on the substrate 1001, and Wₙ₋₁ represents a width of an individual device to be defined in an (n−1)^{th} device layer Lₙ₋₁ (note: in this article, the device layer and its related features such as width will be numbered from bottom to top, as shown in the figure). In this embodiment, n=3, so (H+W)>(W₁−W₂). This relationship ensures that when the photoresist is subsequently trimmed, the photoresist may remain in contact with the cushion layer 1013 without separating from each other before the photoresist is completely removed.

In addition, as shown in FIG. 3, a photoresist 1015 may be further formed on the hard mask layer 1011. The photoresists 1015 may be patterned as linear patterns that are separated from each other in the first direction, extending along the second direction and overlapping a corresponding pattern of the cushion layer 1013 on one side, so as to define the active regions of individual devices in each device layer (in combination with the corresponding pattern in the cushion layer 1013). A width (as shown in the arrowed line segment in FIG. 3) of the pattern of the photoresist 1015 and corresponding pattern of the cushion layer 1013 in the transverse direction (herein, the first direction) may correspond to the width W₁ of the individual device in the lowest first device layer L₁. In addition, a thickness of the photoresist 1015 in the vertical direction may be greater than (H+W), so as to ensure that when the photoresist is subsequently trimmed, the photoresist may remain in contact with the cushion layer 1013 without separating from each other before the photoresist is completely removed.

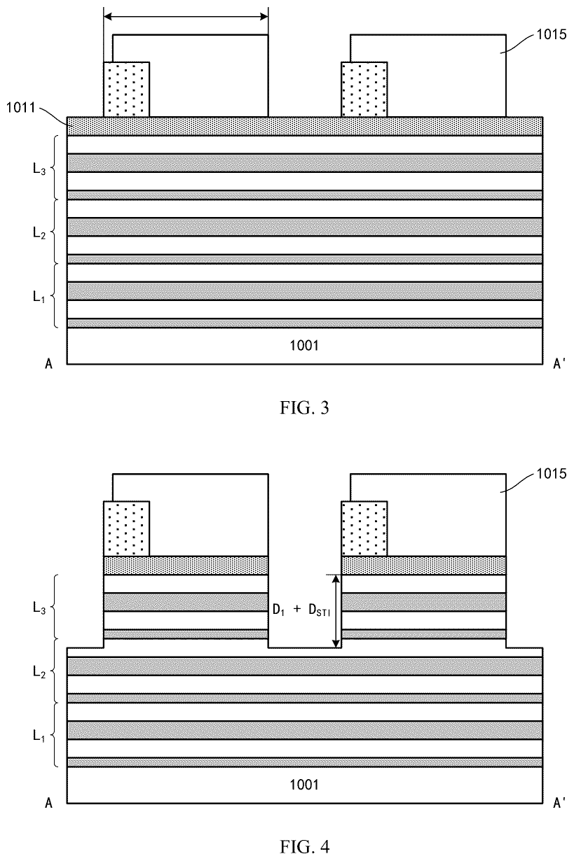

Then, as shown in FIG. 4, etching such as reactive ion etching (RIE) may be performed on the device layer by using the cushion layer 1013 and the photoresist 1015 as etching masks. Herein, the etching recipe may substantially have no selectivity for each layer (such as Si and SiGe) in the device layer. An etching depth may be controlled to be a sum of a thickness D₁ of the first device layer L₁ and a depth D_{STI} of an STI to be formed, that is, D₁+D_{STI}. For example, D_{STI} may be about 50 nm to 200 nm.

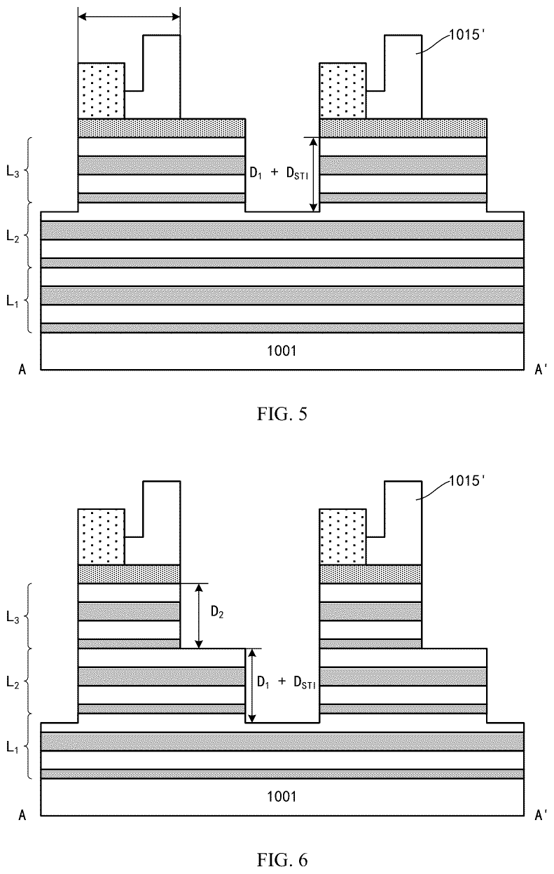

As shown in FIG. 5, the photoresist 1015 may be trimmed, such that the trimmed photoresist 1015′ combined with the cushion layer 1013 may define an active region of an individual device in the second device layer L₂. Specifically, a width (as shown in the arrowed line segment in FIG. 5) of the pattern of the photoresist 1015′ and corresponding pattern of the cushion layer 1013 in the transverse direction (here, the first direction) may correspond to a width W₂ of an individual device in the second device layer L₂. That is, the amount of the photoresist 1015 required to be trimmed is (W₁-W₂).

Then, as shown in FIG. 6, etching such as RIE may be performed on the device layer by using the cushion layer 1013 and the photoresist 1015′ as etching masks. Similarly, the etching recipe may substantially have no selectivity for each layer in the device layer. The etching depth may be controlled as a thickness D₂ of the second device layer L₂.

More generally, the photoresist trimming process described in conjunction with FIG. 5 and the etching process described in conjunction with FIG. 6 may be repeated. For example, the photoresist may be sequentially trimmed by amount of (W₁-W₂), (W₂-W₃), (W₃-W₄), . . . , and (Wₙ₋₂-Wₙ₋₁) (a total amount of the photoresist trimmed is (W₁-W₂)+(W₂-W₃)+(W₃-W₄)+ . . . +(Wₙ₋₂-Wₙ₋₁)=(W₁-Wₙ₋₁), which is also the reason why this term appears in the above relationship). After each photoresist trimming, the trimmed photoresist combined with the cushion layer 1013 is used as the etching mask to etch the device layer. The etching depth may be a thickness D₂ of the second device layer L₂, a thickness D₃ of the third device layer L₃, . . . , and a thickness Dₙ₋₁ of an (n−1)^{th} device layer Lₙ₋₁ in sequence.

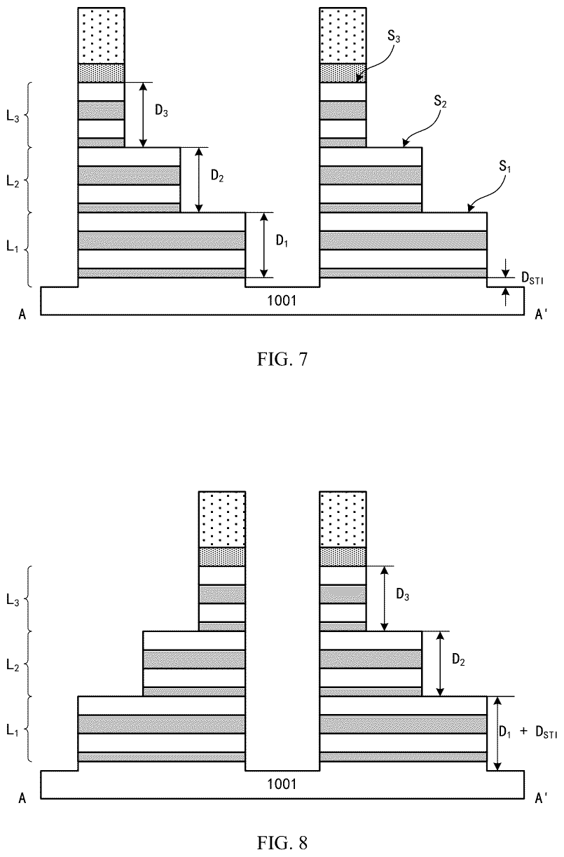

Afterwards, as shown in FIG. 7, the photoresist may be further trimmed (in this example, the photoresist 1015′ may be removed by a last trimming). A width W of the pattern of the cushion layer 1013 may correspond to a width W₃ of an individual device in the uppermost third device layer L₃. Etching such as RIE may be performed on the device layer by using the cushion layer 1013 as an etching mask. Similarly, the etching recipe may have substantially no selectivity for each layer in the device layer. The etching depth may be controlled as a thickness D₃ of the third device layer L₃.

More generally, the photoresist that has been trimmed one or more times as described above may be removed to leave the cushion layer 1013. The cushion layer 1013 is used as the etching mask to etch the device layer. An etching depth may be a thickness Dₙ of an n^{th} device layer La.

Accordingly, a step structure shown in FIG. 7 is formed. As shown in FIG. 7, the lower device layer protrudes relative to the upper device layer, so as to form respective steps S₁ and S₂. In addition, a top portion of the uppermost device layer (in this example, the third device layer L₃) may also be referred to as a step S₃. The steps S₁, S₂ and S₃ may be in shapes of a plate extending in the second direction. At each step S₁, S₂ and S₃, the second/drain layer of corresponding device layers L₁, L₂ and L₃ may be exposed. In addition, the semiconductor layers in the same device layer may be substantially aligned in the vertical direction. In the example in FIG. 7, it is shown that steps S₁ and S₂ in the step structure are defined by original top surfaces of respective second/drain layers 1009₁ and 1009₂ in the corresponding device layers L₁ and L₂, which is an ideal situation. In a practical process, exposed portions of the second/drain layers 1009₁ and 1009₂ in the device layers L₁ and L₂ may be etched off by a certain thickness.

In addition, a groove extending in the second direction is formed in the substrate 1001, and the groove may be used to form an STI subsequently.

An orientation of the step structure is not limited to that shown in FIG. 7. According to the circuit design, the step structure may have different orientations. For example, as shown in FIG. 8, respective step structures of devices adjacent in the first direction may face opposite directions. In the following, for the convenience of description only, a situation shown in FIG. 7 will be taken as an example for description. The orientation shown in FIG. 7 has an advantage of a relatively large processing space (especially at the top).

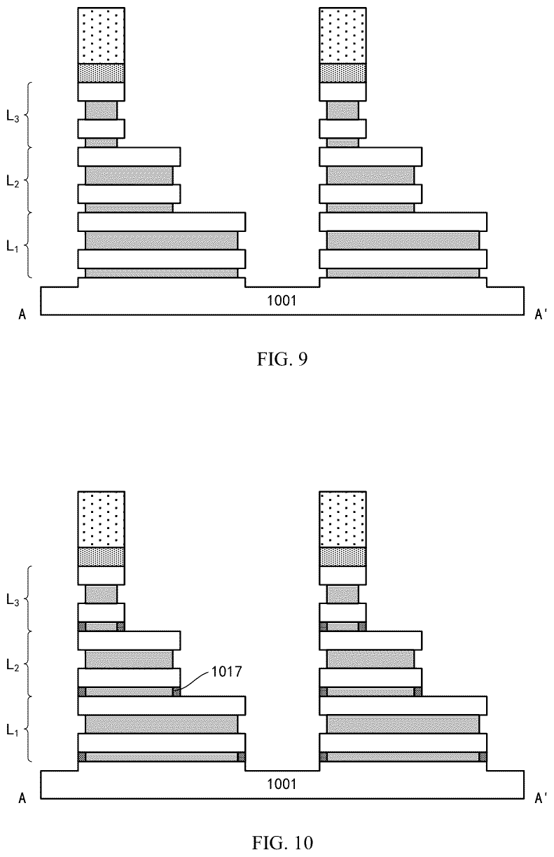

In order to form the GAA configuration, a sacrificial gate may be formed on two opposite sides of the channel defining layers 1007₁, 1007₂ and 1007₃ in the first direction. For example, as shown in FIG. 9, the channel defining layers 1007₁, 1007₂ and 1007₃ (in this example, SiGe) in each device layer may be relatively recessed in the first direction by selectively etching, so as to provide a space for forming the sacrificial gate. In this example, the isolation defining layers 1003₁, 1003₂ and 1003₃ (in this example, also SiGe) will also be relatively recessed by a substantially same extent in the first direction. For example, etching depths for the channel defining layers 1007₁, 1007₂ and 1007₃ as well as the isolation defining layers 1003₁, 1003₂ and 1003₃ may be about 2 nm to 10 nm. The etching depth in each device layer may be substantially the same. Atomic layer etching (ALE) may be adopted in order to better control the etching depth.

In order to avoid the sacrificial gate being formed in the relative recesses of the isolation defining layers 1003₁, 1003₂ and 1003₃ (which is undesired), as shown in FIG. 10, a plug 1017 may be formed in the relative recesses of the isolation defining layers 1003₁, 1003₂ and 1003₃. The plug 1017 may include a material with an etching selectivity relative to the hard mask layer 1011 and the cushion layer 1013, such as SiC. Since the thickness of each channel defining layer is greater than the thickness of each isolation defining layer as mentioned above, the plug 1017 may not be formed in the relative recesses of the channel defining layers 1007₁, 1007₂ and 1007₃. Specifically, SiC with a thickness greater than a maximum thickness in each isolation defining layer but less than half of a minimum thickness in each channel defining layer may be deposited. Accordingly, the relative recesses of the isolation defining layers 1003₁, 1003₂ and 1003₃ may be completely filled with the deposited SiC. The deposited SiC may be etched back by a certain thickness (for example, slightly greater than the deposited thickness), so that SiC may be left in the relative recesses of the isolation defining layers 1003₁, 1003₂ and 1003₃ to form the plug 1017, and SiC may be removed from the relative recesses of the channel defining layers 1007₁, 1007₂ and 1007₃.

In a case that the isolation defining layers 1003₁, 1003₂ and 1003₃ have the etching selectivity relative to the channel defining layers 1007₁, 1007₂ and 1007₃, the formation of the plug 1017 may be omitted.

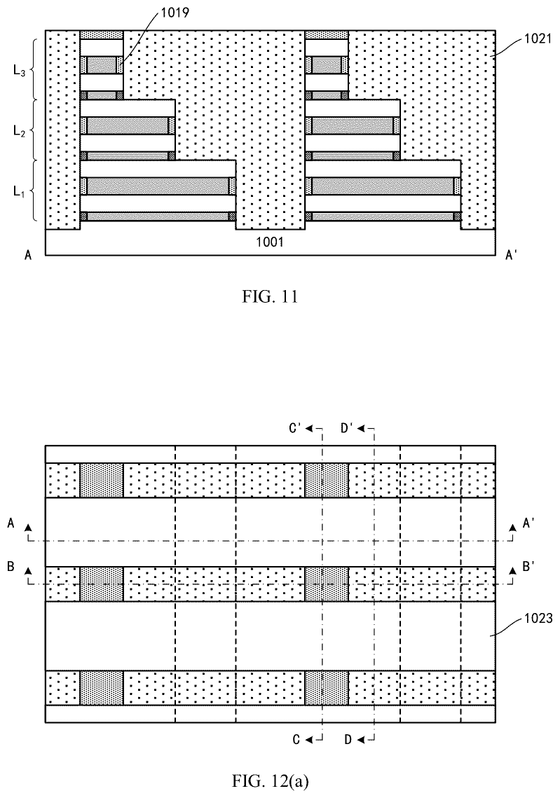

Afterwards, as shown in FIG. 11, a sacrificial gate 1019 (which may be referred to as “first sacrificial gate”) may be formed in the relative recesses of the channel defining layers 1007₁, 1007₂ and 1007₃. The first sacrificial gate 1019 may include a material with an etching selectivity relative to the plug 1017, such as a nitride. For example, the nitride may be deposited and RIE in the vertical direction may be performed on the deposited nitride, so as to form the first sacrificial gate 1019.

In addition, the dielectric such as oxide may be deposited and performed a planarization such as chemical mechanical polishing (CMP) (which may be stopped at the hard mask layer 1011), so as to form an isolation material 1021. Gaps in the device layer caused by the above processes may be filled with the isolation material, in order to facilitate subsequent processes.

Through the process of forming the step structure mentioned above, respective device layers are separated in the first direction, but still continuously extend in the second direction. Next, the device layers may be separated in the second direction.

As shown in FIGS. 12(a) to 12(c), a photoresist 1023 may be formed on the isolation material 1021 and patterned as a pattern separated in the second direction, such as a strip extending along the first direction. An active region of the individual device is defined at an intersection of these strips extending in the first direction and respective previously formed device layers extending in the second direction.

An isolation may be formed in regions exposed between these stripe patterns of the photoresist 1023. Specifically, active layers in these regions may be removed and filled with dielectrics.

In FIG. 12(a), the line AA′ extends in the first direction and a cross-section (perpendicular to a surface of the substrate) represented by the line AA′ passes through the active region (especially passes through a portion of a subsequently formed channel layer 1033 that is used as a channel). The line BB′ extends in the first direction and a cross-section (perpendicular to the surface of the substrate) represented by the line BB′ passes through a subsequently formed STI. The line CC′ extends in the second direction and a cross-section (perpendicular to the surface of the substrate) represented by the line CC′ passes through the step S₃. The line DD′ extends in the second direction and a cross-section (perpendicular to the surface of the substrate) represented by the line DD′ passes through the step S₂.

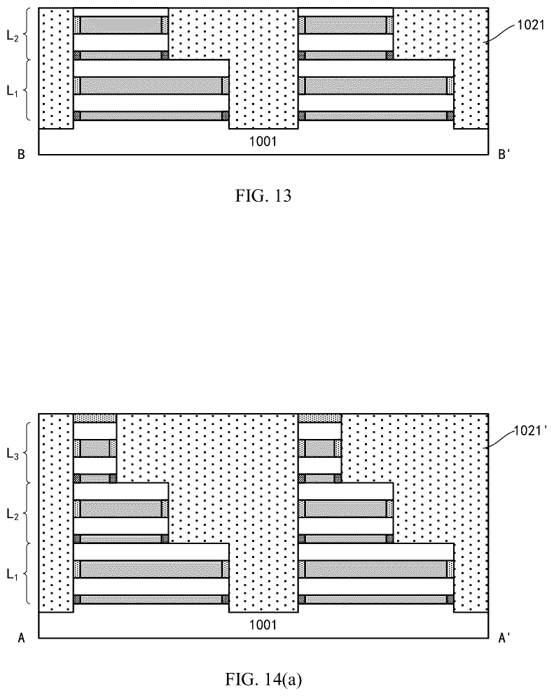

For example, as shown in FIG. 13, the hard mask layer 1011 in these regions may be removed by RIE to expose the lower device layer (in this case, the third device layer L₃). Then, the exposed third device layer L₃ may be removed by, for example, RIE. Herein, the etching depth may be controlled, so that the etching is stopped close to a top surface of the second source/drain layer 1009₂ of the second device layer L₂. A portion of the second source/drain layer 1009₂ of the second device layer L₂ originally covered by the third device layer L₃ may be exposed due to a removal of the third device layer L₃, while the other one portion (that is, step S₂) is covered by the isolation material 1021. A certain thickness of the isolation material 1021 may be reduced by, for example, RIE. The top surface of the isolation material 1021 whose thickness is reduced may be close to the top surface of the second source/drain layer 1009₂ of the second device layer, so as to expose a substantially entire second source/drain layer 1009₂ of the second device layer L₂, including the step S₂.

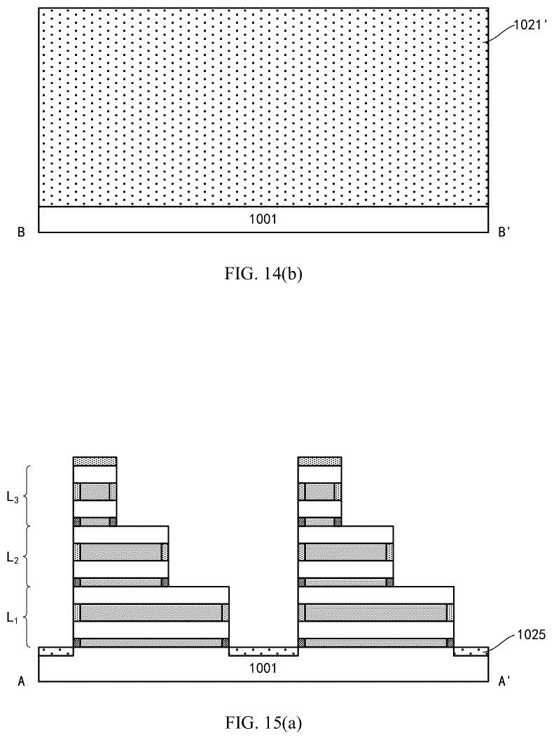

As shown in FIGS. 14(a) and 14(b), such process may be repeated, that is, removing substantially one device layer and reducing the thickness of the isolation material 1021 by amount substantially the same as the thickness of such device layer (so that a top surface of a next device layer may be completely exposed) until a depth of an STI to be formed is reached. Afterwards, the photoresist 1023 may be removed. Accordingly, each device layer is separated into active regions of individual devices. Gaps between these active regions may be filled with the dielectric by methods such as deposition followed by planarization such as CMP (which may be stopped at the hard mask layer 1011). The dielectric filled herein may include the same dielectric as the previous isolation material 1021, such as oxide, and thus they are integrally shown as an isolation material 1021′.

Then, as shown in FIGS. 15(a) to 15(c), the isolation material 1021′ may be etched back by dry etching such as RIE or wet etching. The etched back isolation material may form an STI 1025 with a thickness of about D_{STI}. It is noted that in the drawings, for the convenience of illustration only, a top surface of the STI 1025 is shown flush with a top surface of the substrate 1001. The top surface of the STI 1025 may be (slightly) lower or (slightly) higher than the top surface of the substrate 1001. As shown in FIG. 15(c), each device layer is separated into the active regions of individual devices in the second direction.

Through the above processes, the active regions of individual devices are defined, and a step structure is formed in the first direction between the active regions stacked.

Herein, in respective device layers, since the first source/drain layer, the channel defining layer (defining the subsequently formed gate stack), and the second source/drain layer are stacked, a step structure may be formed in respective device layers for easy connection to each of them. The step structure may be formed in the second direction, so as to avoid interference with the above-mentioned step structure formed in the first direction. In addition, considering that the respective lower channel defining layer and second source/drain layer require to protrude relative to each other, a step structure may be formed on two opposite sides in the second direction.

The two opposite sides in the second direction may be processed separately. During the process, a shielding layer may be used to shield other sides and expose a side that requires to be processed.

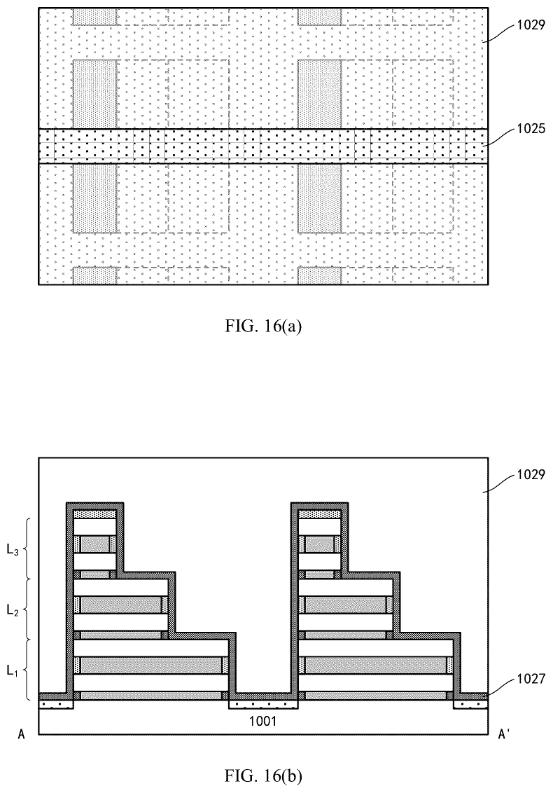

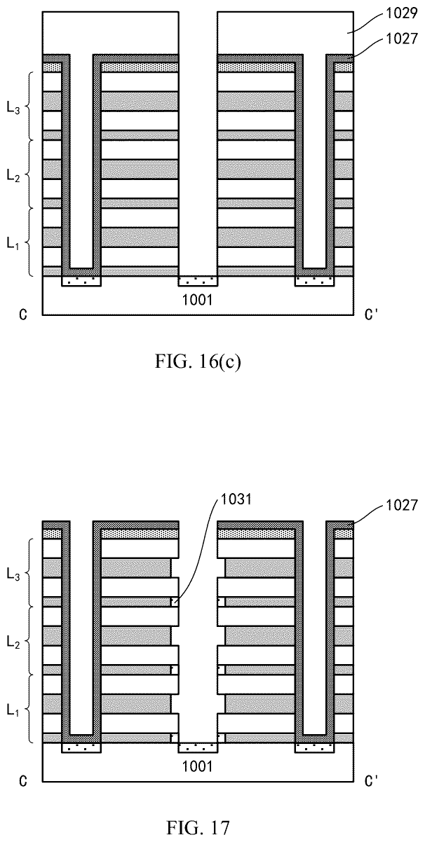

For example, as shown in FIGS. 16(a) to 16(c), a shielding layer 1027 may be formed in a substantially conformal manner by, for example, deposition. For example, the shielding layer 1027 may include a material with an etching selectivity relative to the hard mask layer 1011, the first sacrificial gate 1019, and the STI 1025, such as SiC. A photoresist 1029 may be formed on the shielding layer 1027 (in FIG. 16(a), to aid understanding, the photoresist 1029 is displayed as partially transparent to display a structure below). The photoresist 1029 is patterned to expose a side of each active region in the second direction. In the illustrated embodiment, the photoresist 1029 exposes a region between every two adjacent active regions in the second direction. Etching such as RIE may be performed on the shielding layer 1027 by using the photoresist 1029 as an etching mask, so that the side of each active region in the second direction is exposed. Afterwards, the photoresist 1029 may be removed. It is noted that in FIG. 16(a), in order to facilitate the reader's understanding of a relationship between the photoresist and the active region, the shielding layer 1027 is not shown.

In this example, for the convenience of patterning, opposite sides (in FIG. 16(a), the upper side and the lower side) of two adjacent active regions in the second direction are exposed. Of course, the present disclosure is not limited thereto. For example, the shielding layer may expose the same side of each active region in the second direction.

As mentioned above in conjunction with FIG. 10, in order to avoid the formation of the sacrificial gate on a periphery of the isolation defining layers 1003₁, 1003₂ and 1003₃, as shown in FIG. 17, the isolation defining layers 1003₁, 1003₂ and 1003₃ (at the same time, the channel defining layers 1007₁, 1007₂ and 1007₃) may be relatively recessed in the second direction by selectively etching such as ALE, so as to form a recess. A plug 1031 is formed in the formed recess. Regarding the formation of the plug 1031, for example, the above description in conjunction with FIG. 10 may be referred to. The plug 1031 may include a material with an etching selectivity relative to the hard mask layer 1011 and the shielding layer 1027, such as oxide.

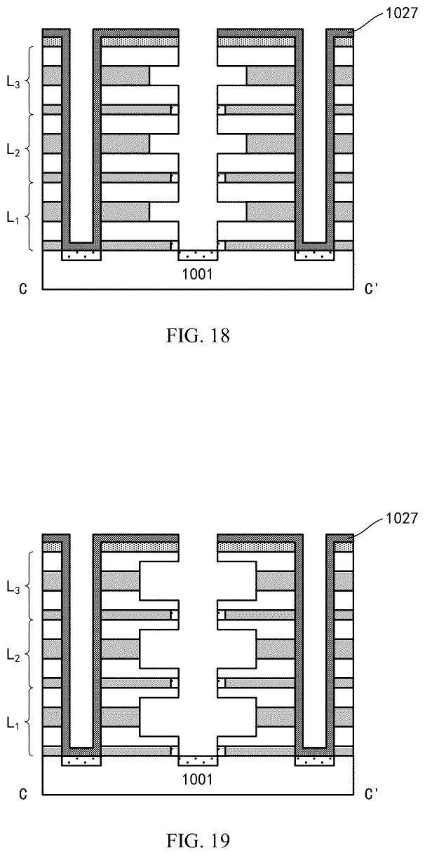

As shown in FIG. 18, through surfaces exposed on one side of each channel defining layer 1007₁, 1007₂ and 1007₃ in the second direction, each channel defining layer 1007₁, 1007₂ and 1007₃ may be further recessed by selectively etching such as ALE, so as to define a gate space. Due to the presence of the plug 1031, the isolation defining layers 1003₁, 1003₂ and 1003₃ may not be affected.

Since the channel defining layers 1007₁, 1007₂ and 1007₃ may have the same material (in this example, SiGe) and may be etched by the same etching recipe, a recessed degree of each channel defining layer 1007₁, 1007₂ and 1007₃ may be substantially the same on the side in the second direction, and sidewalls after being recessed may remain substantially aligned in the vertical direction and may remain substantially coplanar.

In another embodiment, as shown in FIG. 19, an etching recipe capable of acting on both the channel defining layer and the source/drain layer may also be used to further etch, by ALE, the channel defining layer and the source/drain layer by a certain depth T. This helps to achieve consistent gate lengths.

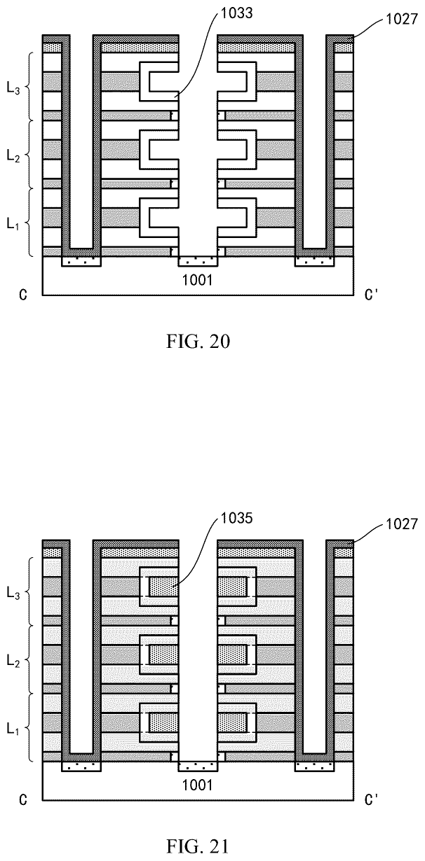

As shown in FIG. 20, a channel layer 1033 may be formed by, for example, epitaxial growth. For example, the channel layer 1033 may include a semiconductor material such as Si that has an etching selectivity relative to the channel defining layer. A growth of the channel layer 1033 is controlled, so that a thickness of the channel layer 1033 is substantially equal to T. In this way, substantially consistent gate lengths (that is, substantially the thickness of the channel defining layer in the vertical direction) may be maintained on two opposite sides of the channel layer 1033 in the second direction (left and right sides within the paper plane in FIG. 20). The channel layer 1033 may be formed in a form of a nanosheet.

The epitaxial growth may also occur on other semiconductor surfaces. The epitaxial grown channel layer may be etched, for example, by RIE in the vertical direction, so that it may be left below the hard mask layer 1011, while the gaps between respective active regions may still be retained as processing channels for further processing.

As shown in FIG. 21, a sacrificial gate 1035 (which may be referred to as “second sacrificial gate”) may be formed in the gate space by, for example, deposition followed by RIE in the vertical direction. The second sacrificial gate 1035 may include the same material as the first sacrificial gate 1019, such as nitride, so that the first sacrificial gate 1019 and the second sacrificial gate 1035 may be simultaneously removed in the subsequent replacement gate process.

In addition, an annealing process may be performed to drive a dopant from the source/drain layer into a portion of the channel layer 1033 that is used as the source/drain, so as to reduce an external resistance and improve the device performance. In FIG. 21, an interface between the portion (such as a portion that extends substantially horizontally) of the channel layer 1033 that is used as the source/drain and a portion (such as a portion that extends substantially vertically) of the channel layer 1033 that is used as a channel is schematically shown with dotted lines. Such interface may be defined by a doping concentration. Diffusions of dopants to portions of the channel layer 1033 that are used as sources/drains on upper and lower sides of the channel layer 1033 may have substantially the same characteristics, so that the portion of the channel layer 1033 that is used as the channel may be self-aligned with a corresponding channel defining layer.

In the following, for the convenience of illustration only, the difference between the portion of the channel layer 1033 that is used as the source/drain and the portion of the channel layer 1033 that is used as the channel will not be shown below.

On the side in the second direction, as shown in FIGS. 22(a) and 22(b), portions of the second source/drain layers 1009₁, 1009₂, 1009₃, and channel layer 1033 (here, all Si) located on a top surface of the second sacrificial gate 1035 may be recessed in the second direction (portions of the first source/drain layers 1005₁, 1005₂, 1005₃, and channel layer 1033 located on a bottom surface of the second sacrificial gate 1035 may also be recessed in the second direction) by selectively etching such as ALE. A recessing depth may ensure an integrity of the portion (herein, a vertical extension portion) of the channel layer 1033 that is used as the channel. Accordingly, in each device layer, the second sacrificial gate 1035 protrudes relative to the second source/drain layers 1009₁, 1009₂, 1009₃ (and the channel layer 1033), so as to form a “sub” step.

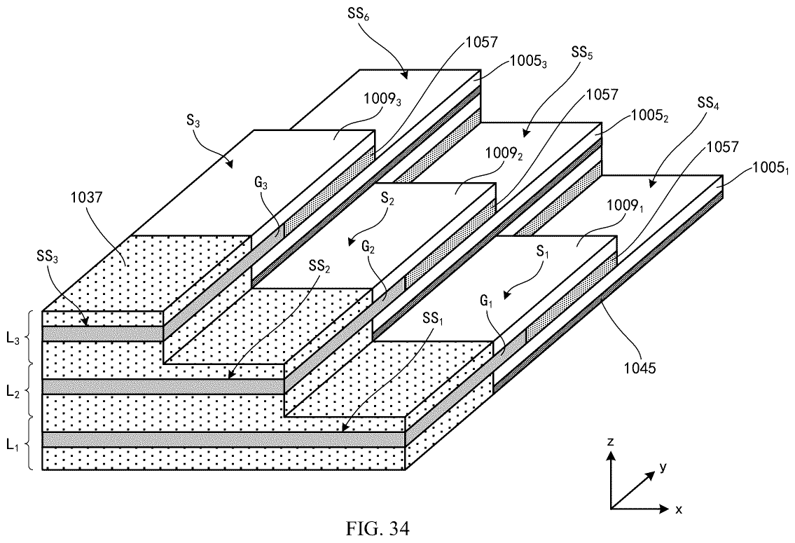

That is, sub-steps SS₁ (see FIG. 34), SS₂ and SS₃ are formed on the side of the second sacrificial gate of each device layer in the second direction relative to the second source/drain layer in the corresponding device layer. It is noted that a reason why such protruding portion is referred to as “sub-step” herein is that, these sub-steps may be formed on the corresponding steps (as mentioned above, FIG. 22(a) shows a situation at the step S₃, and FIG. 22(b) shows a situation at the step S₂).

In addition, due to the recess of the source/drain layer and the channel layer 1033, ends of the isolation defining layers 1003₁, 1003₂ and 1003₃, as well as the plug 1031 may be suspended and thus be removed due to erosion during etching process.

Alternatively, the plug 1031 may be removed before selectively etching. The etching recipe may be selected to work on the second source/drain layers 1009₁, 1009₂ and 1009₃, the channel layer 1033, and the isolation defining layers 1003₁, 1003₂ and 1003₃. Accordingly, the isolation defining layers 1003₁, 1003₂ and 1003₃ may be recessed along with the second source/drain layers 1009₁, 1009₂ and 1009₃, as well as the channel layer 1033.

The gap formed below the shielding layer 1027 due to such recessing may be filled with a dielectric 1037 (such as oxide) by deposition, planarization (which may be stopped at the shielding layer 1027) followed by etching back. Due to the presence of the shielding layer 1027, the dielectric 1037 is formed below the shielding layer 1027. FIG. 22(b) shows a situation at the step S₂ between the second device layer L₂ and the third device layer L₃, which is same as a situation at the step S₁ between the first device layer L₁ and the second device layer L₂. That is, a step structure is formed by the dielectric 1037 along with each device layer. That is, the gate space defined by the dielectric 1037 may maintain the previously formed step structure.

In view of above, one side of each active region in the second direction is processed through the shielding layer 1027. Afterwards, the other side of each active region in the second direction may be processed.

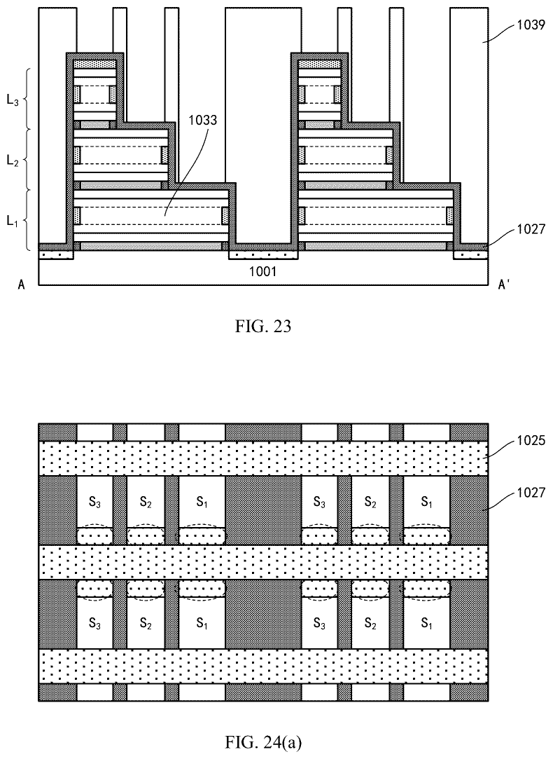

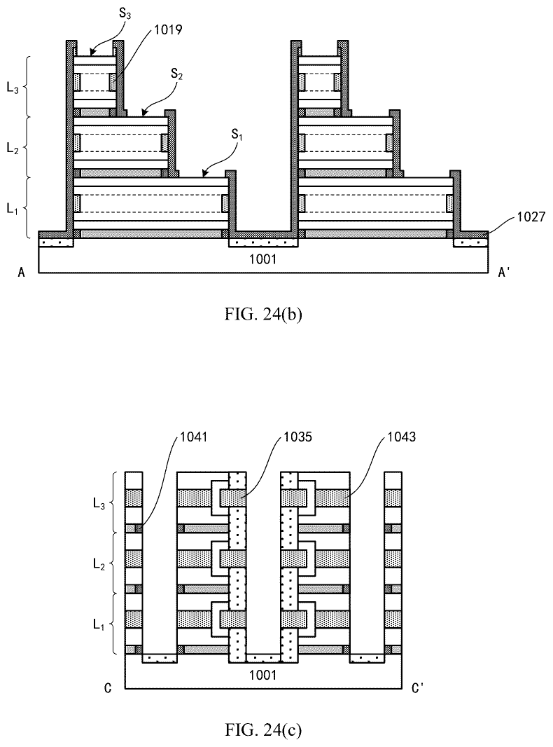

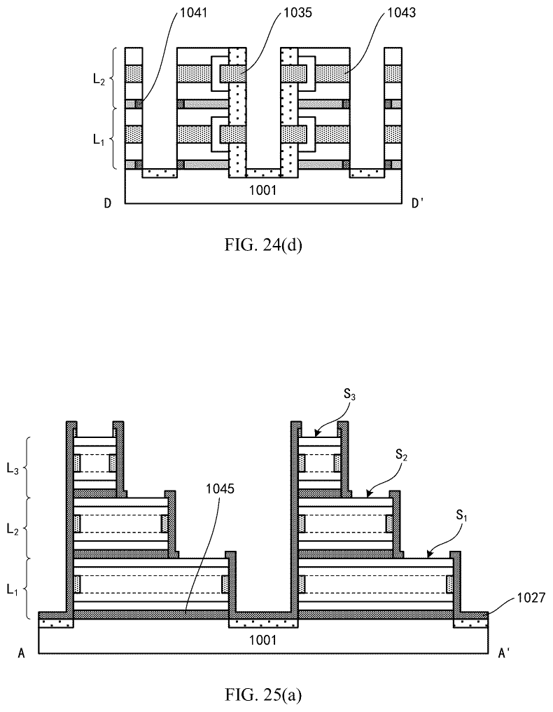

To this end, as shown in FIG. 23, a photoresist 1039 may be formed on the shielding layer 1027 and patterned to expose the other side of each active region in the second direction (see FIG. 24(a), the “other side” is the side of each active region that is shielded by the shielding layer 1027 in the second direction as shown in FIG. 16(a)). Herein, on the side that has already been processed in the second direction, due to the presence of the dielectric 1037 and second sacrificial gate 1035 (as shown in the dotted circle in FIG. 24(a)), it is not required to form a separate shielding layer.

In addition, considering a silicification process performed to reduce the contact resistance, the photoresist 1039 may be patterned to (at least partially) expose each step while and shield vertical sidewalls of each device layer. FIGS. 24(a) to 24(d) show structures after etching such as RIE is performed on the shielding layer 1027 by using the photoresist 1039 as an etching mask. Afterwards, the photoresist 1039 may be removed.

Herein, a cross-section intercepted based on the line AA′ passes through the channel layer 1033, thus the channel layer 1033 exists in the cross-sectional view shown in FIG. 23. In addition, FIG. 23 schematically shows the interface between the portion of the channel layer 1033 that is used as the source/drain and the portion of the channel layer 1033 that is used as the channel with dotted lines. As shown in FIG. 23, in the first direction, a gate width may be defined by a width of the portion of the channel layer 1033 that is used as the channel. Therefore, a width of the first sacrificial gate 1019 in the first direction may be relatively small to avoid reducing the gate width. In addition, in the vertical direction, a gate length may be defined by a height of the portion of the channel layer 1033 that is used as the channel and may be substantially equal to a thickness of the channel defining layer in the vertical direction. The channel layer 1033 may be in the form of the nanosheet, so that the size of the channel layer 1033 in the second direction may be (much) less than the width of the channel layer 1033 in the first direction and the height of the channel layer 1033 in the vertical direction.

A plug 1041 may be formed as described above in combination with FIGS. 16(a) to 16(c). The plug 1041 may include a material with an etching selectivity relative to the second sacrificial gate 1035 and the dielectric 1037, such as SiC. In a case that the plug 1041 includes SiC, a thin etch stop layer such as an oxide may be formed by deposition first. This helps to avoid affecting the shielding layer 1027′, which is also SiC, when forming the plug 1041.

Then, the channel defining layers 1007₁, 1007₂ and 1007₃ may be removed by selectively etching (due to the presence of the plug 1041, the isolation defining layers 1003₁, 1003₂ and 1003₃ may be avoided from being removed herein). In the gate space left by the removal of the channel defining layers 1007₁, 1007₂ and 1007₃, a sacrificial gate 1043 (which may be referred to as “third sacrificial gate”) may be formed by deposition followed by RIE in the vertical direction. The third sacrificial gate 1043 may include the same material (in this case, nitride) as the first sacrificial gate 1019 and the second sacrificial gate 1035, so that they may be subsequently removed together. In the RIE process of forming the third sacrificial gate 1043, the portion of the hard mask layer 1011, which is also a nitride and not shielded by the shielding layer 1027′, may also be removed.

The first sacrificial gate 1019 is located on two opposite sides of the channel layer 1033 (specifically, the portion of the channel layer 1033 that is used as the channel) in the first direction, and the third sacrificial gate 1043 and the sacrificial gate 1035 are respectively located on two opposite sides of the channel layer 1033 (specifically, the portion of the channel layer 1033 that is used as the channel) in the second direction. That is, each sacrificial gate surrounds the periphery of the channel layer 1033 (specifically, the portion of the channel layer 1033 that is used as the channel). In addition, as mentioned above, each sacrificial gate may have substantially the same gate length, which is about equal to the thickness of the channel defining layer in the vertical direction.

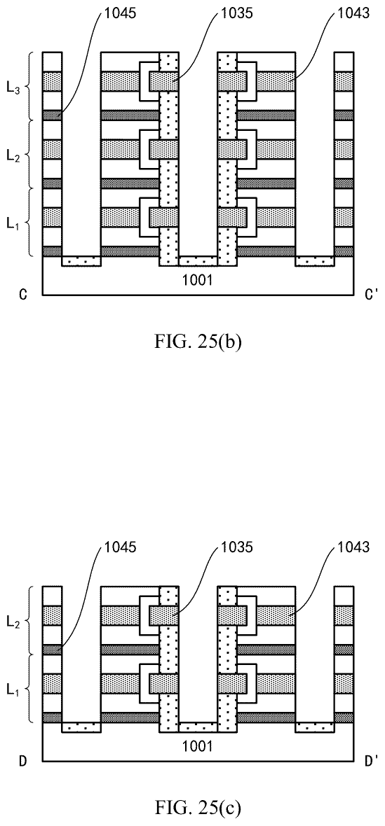

The isolation defining layer may be replaced by an isolation material, so as to achieve electrical isolation between devices adjacent in the vertical direction. For example, as shown in FIGS. 25(a) to 25(c), the plug 1041 may be removed by selectively etching, so as to expose the isolation defining layers 1003₁, 1003₂ and 1003₃. Then, the isolation defining layers 1003₁, 1003₂ and 1003₃ may be removed by selectively etching. In the space left by the removal of the isolation defining layers 1003₁, 1003₂ and 1003₃, an isolation layer 1045 may be formed by deposition followed by etching back, so as to achieve the electrical isolation. The isolation layer 1045 may include a dielectric material with an etching selectivity relative to the sacrificial gates 1019, 1035, 1043 (herein, nitride) and the dielectric 1037 (herein, oxide), such as SiC.

With reference to FIG. 25(a), through each step S₁, S₂ and S₃, the second source/drain layers 1009₁, 1009₂ and 1009₃ of each device layer may have exposed surfaces for subsequent manufacturing contact portions to the second source/drain layers 1009₁, 1009₂ and 1009₃. At each step S₁, S₂ and S₃, the first source/drain layers 1005₁, 1005₂ and 1005₃ of each device layer may also be exposed for subsequent manufacturing contact portions to the first source/drain layers 1005₁, 1005₂ and 1005₃.

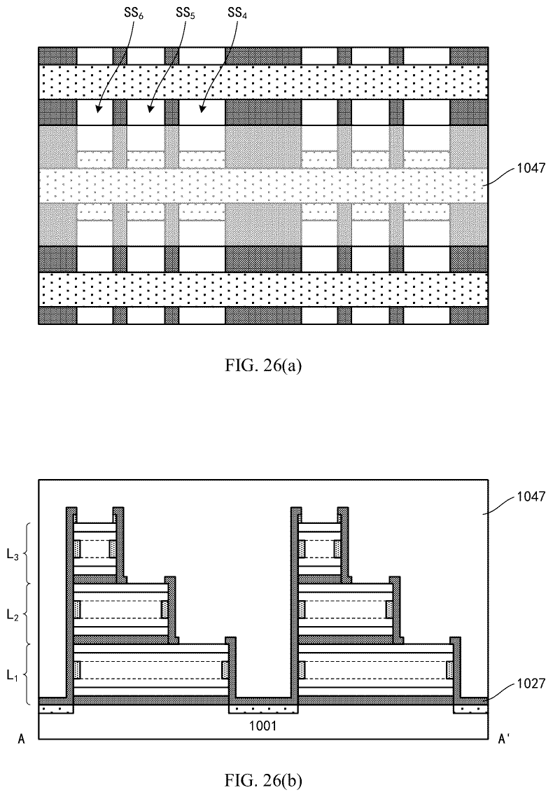

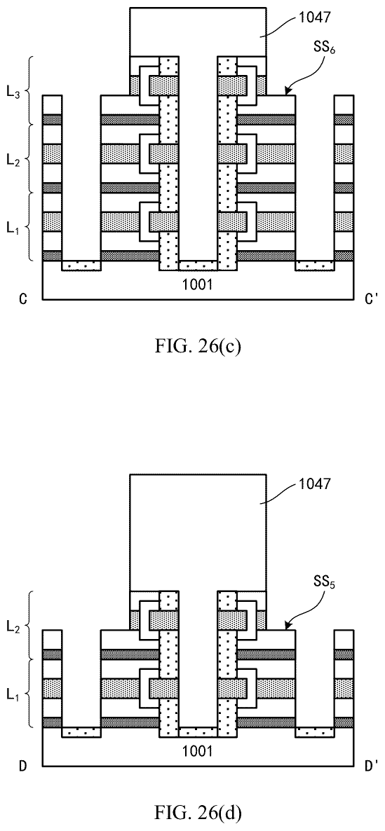

For example, as shown in FIGS. 26(a) to 26(c), a photoresist 1047 may be formed (in FIG. 26(a), to aid understanding, the photoresist 1047 is displayed as partially transparent to display the structure below), and the photoresist 1047 may be patterned to shield a part of each step S₁, S₂ and S₃, while to expose a remaining part of each step S₁, S₂ and S₃. That is, each step S₁, S₂ and S₃ may be divided into two parts (these two parts may have substantially the same area) based on the photoresist 1047. In this example, the photoresist 1047 may be patterned as a strip extending along the first direction, so that each step S₁, S₂ and S₃ may be divided into two parts that are side by side in the second direction, and the part of each step S₁, S₂ and S₃ on the side on which the third sacrificial gate 1043 is located is exposed.

The corresponding second source/drain layer and sacrificial gate may be selectively etched in sequence at each step S₁, S₂ and S₃ by using the photoresist 1047 as an etching mask and selectively etching such as RIE. Accordingly, in each device layer, the first source/drain layer protrudes relative to the second source/drain layer and sacrificial gate at each step S₁, S₂ and S₃, so as to form sub-steps SS₄, SS₅ and SS₆. Afterwards, the photoresist 1047 may be removed.

At this point, the active region (including the first source/drain layer, the second source/drain layer and the channel layer therebetween) and the sacrificial gate (surrounding the channel layer) have been defined in each device layer.

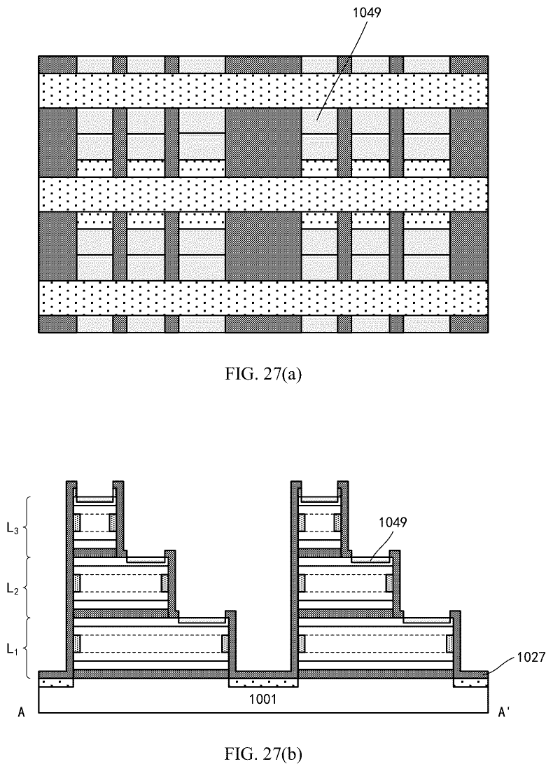

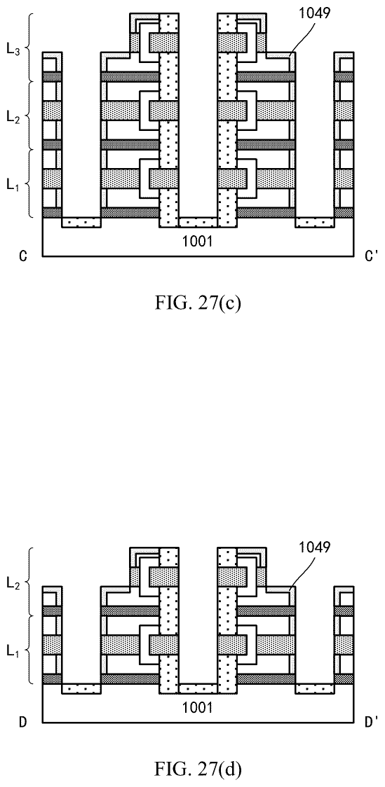

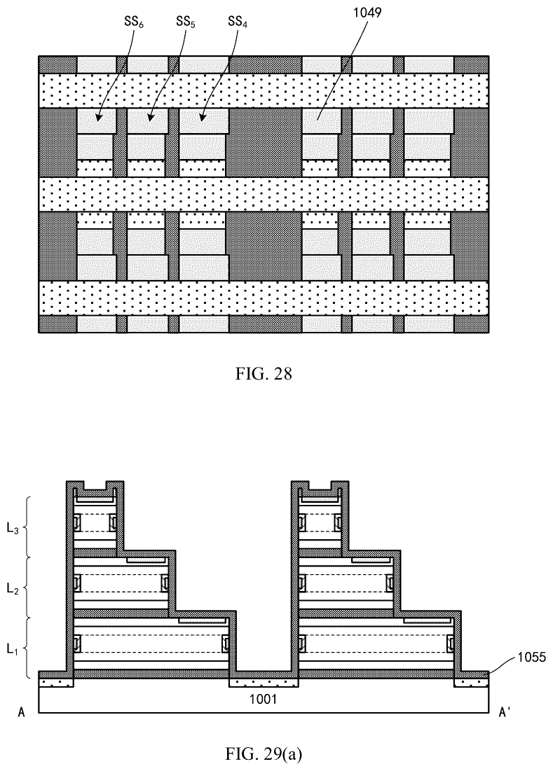

In order to reduce the contact resistance, as shown in FIGS. 27(a) to 27(d), the first source/drain layer and second source/drain layer exposed at each step S₁, S₂ and S₃ may be silicified, so as to form a silicide 1049. For example, the metal such as Ni or NiPt may be deposited and annealed at a temperature of about 300° C. to 700° C., and the deposited metal reacts with semiconductor elements in the first source/drain layer and the second source/drain layer, so as to generate a metal semiconductor compound such as NiSi or NiPtSi. Afterwards, the unreacted remaining metal may be removed.

According to another embodiment, in the process described above in conjunction with FIGS. 26(a) to 26(d), the horizontal extension portion of the portion of the shielding layer 1027′ exposed by the photoresist 1047 may be removed by, such as RIE in the vertical direction, so as to increase the area of each sub-step SS₄, SS₅ and SS₆ (which is beneficial for subsequent manufacturing contact portions to each sub-step SS₄, SS₅ and SS₆). At the same time, the vertical extension portion (as a spacer) of the exposed portion of the shielding layer 1027′ is maintained to protect the sidewall. In this way, the structure shown in FIG. 28 may be obtained.

Next, the replacement gate process may be performed.

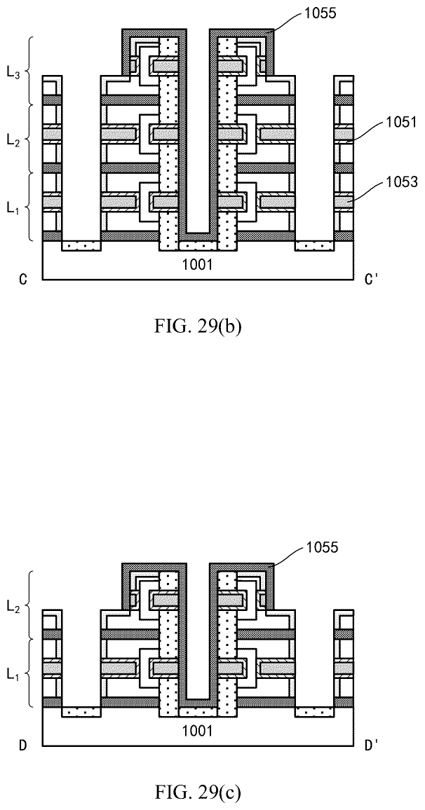

As shown in FIGS. 29(a) to 29(c), the shielding layer 1027′ and sacrificial gates 1019, 1035 and 1043 may be removed by selectively etching. In a space left by the removal of the sacrificial gates 1019, 1035 and 1043, a gate stack may be formed by, for example, deposition followed by RIE in the vertical direction. The gate stack may include a gate dielectric layer 1051 and a gate conductor layer 1053. For example, the gate dielectric layer 1051 may include a high k dielectric such as HfO₂, and the gate conductor layer 1053 may include metal. The gate stack may surround the periphery of the channel layer 1033 (specifically, the portion of the channel layer 1033 that is used as the channel), so as to form a Gate-All-Around (GAA) structure.

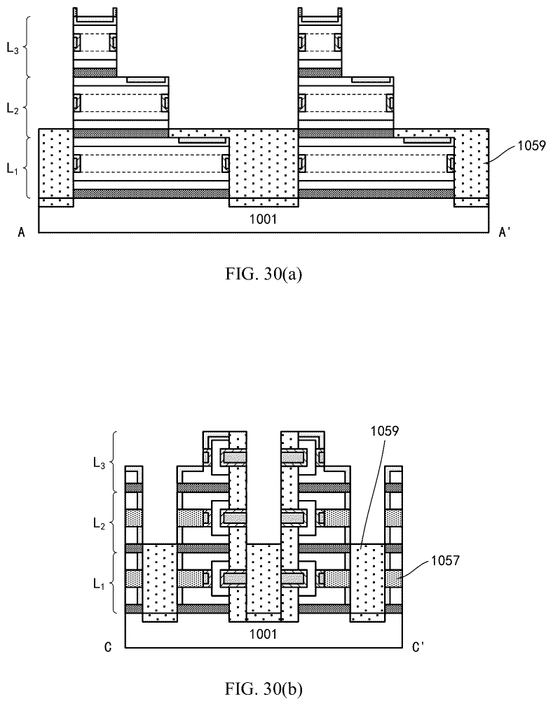

As shown in FIGS. 29(b) and 29(c), a dielectric 1037 exists on one side of each active region in the second direction, so that an overlap between the gate stack and the source/drain is relatively small. On the other side of each active region in the second direction, an overlap between the gate stack and the source/drain is relatively large. In order to reduce such overlap and thus reduce a parasitic capacitance caused by the overlap, a shielding layer 1055, such as SiC, may be formed to shield the relatively small overlap region (on the one side in the second direction) and expose the relatively large overlap region (on the other side in the second direction). In the relatively large overlap region, the gate stack may be recessed by a certain depth by selectively etching (so as to reduce the overlap between the gate stack and the source/drain). A recess formed by the recessing of the gate stack may be filled with the dielectric material (see 1057 in FIG. 30(b)) such as nitride by deposition followed by RIE in the vertical direction. Afterwards, the shielding layer 1055 may be removed.

In the above embodiment, a gate stack (1051/1053) with the same configuration is formed for each device layer. However, the present disclosure is not limited thereto. For example, gate stacks (for example, with different work functions) with different configurations may be formed for at least some device layers, especially when the devices in these device layers have different conductivity types.

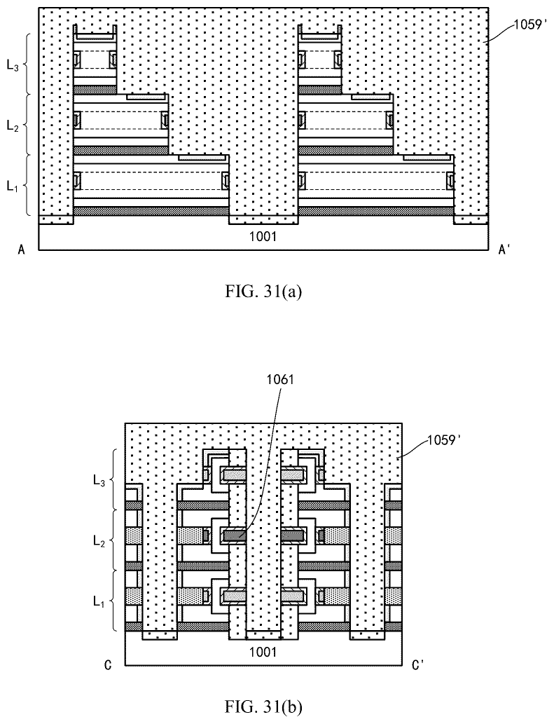

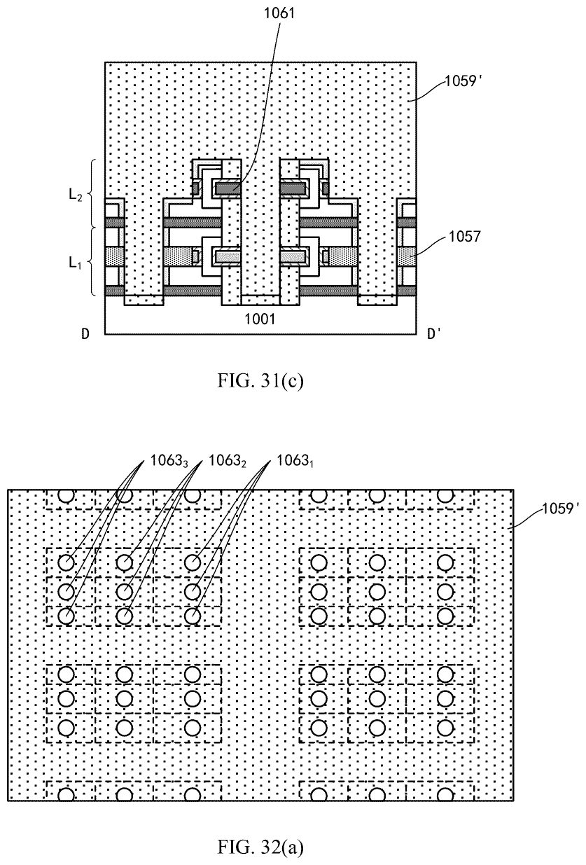

For example, as shown in FIGS. 30(a) and 30(b), after forming a first gate stack (1051/1053) for the first device layer L₁ as described above, an interlayer dielectric layer 1059 (such as oxide) with a certain height may be formed on the substrate 1001 by deposition followed by etching back. The height of the interlayer dielectric layer 1059 is capable of shielding the first gate stack (1051/1053) formed in the first device layer L₁ and exposing the first gate stack (1051/1053) formed in the second device layer L₂ and the third device layer L₃. The gate conductor layer 1053 in the exposed first gate stack may be removed by selectively etching. Accordingly, a part of gate space in the second device layer L₂ and the third device layer L₃ is released. Another gate conductor layer 1061 (see FIGS. 31(a) and 31(b)) may be formed in the released gate space. Accordingly, a second gate stack (1051/1061) for the second device layer L₂ is formed.

Herein, the second gate stack and the first gate stack have the same gate dielectric layer. However, the present disclosure is not limited thereto. For example, the gate dielectric layer 1051 may be removed and another gate dielectric layer may be formed.

In addition, if a third gate stack (which may be the same as the first gate stack or different from the first gate stack) different from the second gate stack is to be formed for the third device layer L₃, a similar process may be performed. For example, a top surface of the interlayer dielectric layer 1059 may be raised by deposition followed by etching back, so as to shield the first gate stack (1051/1053) formed in the first device layer L₁ and the second gate stack (1051/1061) formed in the second device layer L₂, and expose the second gate stack formed in the third device layer L₃. A gate conductor layer 1061 in the exposed second gate stack may be removed by selectively etching. Accordingly, a part of the gate space in the third device layer L₃ is released. A gate conductor layer may be formed in the released gate space.

FIGS. 31(a) and 31(b) show structures after forming corresponding gate stacks for all device layers. An interlayer dielectric layer 1059′ covering all device layers may be formed by deposition followed by planarization.

At this point, the manufacturing of the device has been substantially completed. Various contact portions may be manufactured in the interlayer dielectric layer 1059′, so as to achieve electrical connection.

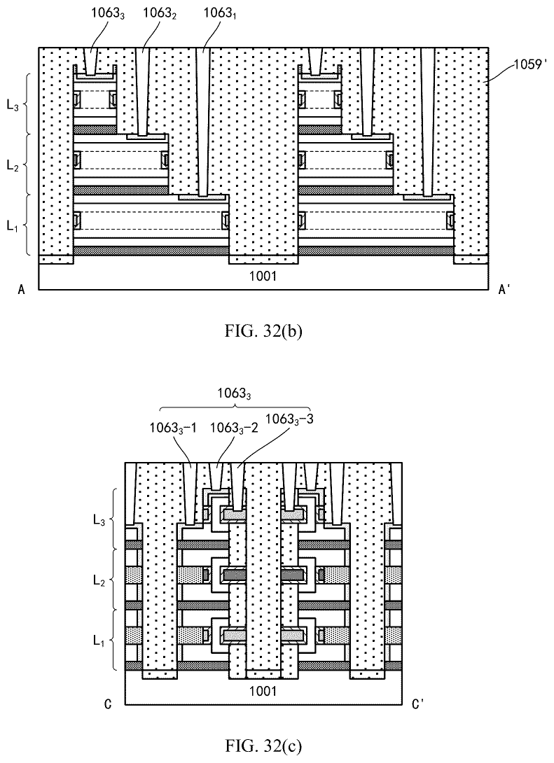

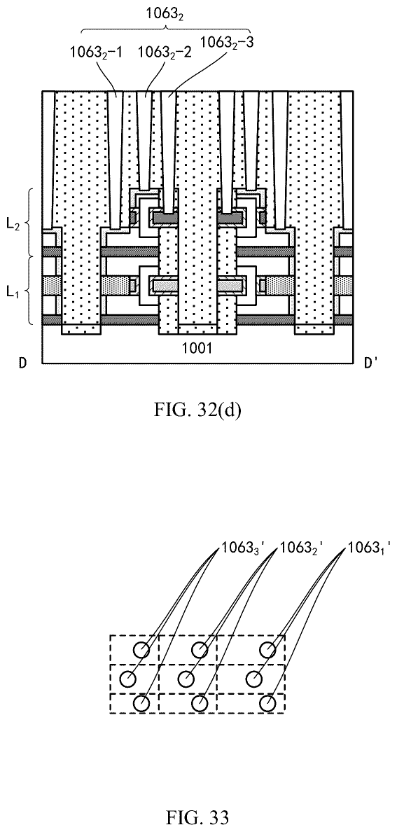

For example, as shown in FIGS. 32(a) to 32(d), contact portions 1063₁, 1063₂ and 1063₃ to the corresponding device layers L₁, L₂ and L₃ are manufactured on each step S₁, S₂ and S₃, respectively. The contact portion may be formed by etching the interlayer dielectric layer 1059′ to form contact holes and filling the holes with a conductive material such as metal. A diffusion barrier layer may be formed first on the sidewalls and bottom surfaces of the contact holes.

In addition, contact portions respectively to the first source/drain layer, second source/drain layer and gate stack in the corresponding device layer may be provided on each step. For example, as shown in FIG. 32(c), on the step S₃, the contact portion 1063₃ may include a contact portion 1063₃-1 (on the sub-step SS₆) to the first source/drain layer in the third device layer L₃, a contact portion 1063₃-2 to the second source/drain layer in the third device layer L₃, and a contact portion 1063₃-3 (on the sub-step SS₃) to the gate stack (in particular, the gate conductor layer therein) in the third device layer L₃. As shown in FIG. 32(a), the contact portions 1063₃-1, 1063₃-2 and 1063₃-3 on the step S₃ may be arranged substantially in a straight line along the second direction. Similarly, as shown in FIG. 32(d), on the step S₂, the contact portion 1063₂ may include a contact portion 1063₂-1 (on the sub-step SS₅) to the first source/drain layer in the second device layer L₂, a contact portion 1063₂-2 to the second source/drain layer in the second device layer L₂ and a contact portion 1063₂-3 (on the sub-step SS₂) to the gate stack (in particular, the gate conductor layer therein) in the second device layer L₂. As shown in FIG. 32(a), the contact portions 1063₂-1, 1063₂-2 and 1063₂-3 on the step S₂ may be arranged substantially in a straight line along the second direction. The same is true for the step S₁, although it is not shown herein.

In the above embodiments, the contact portions on each step are arranged in a straight line. However, the present disclosure is not limited thereto. For example, as shown in FIG. 33, the contact portions on each step may be arranged in a zigzag pattern in the second direction. In this way, in a case that the spacing between the contact portions remains the same, the area may be saved (the size of the device in the second direction may be reduced while the width of the device in the first direction is maintained to be unchanged).

As shown in FIG. 34, a semiconductor apparatus according to an embodiment of the present disclosure may include two or more device layers L₁, L₂, L₃ which are stacked in the vertical direction (z direction), and corresponding devices may be defined in each device layer. Each device layer may include a first source/drain layer, a channel layer, and a second source/drain layer which are stacked in the vertical direction (z direction). As mentioned above, the channel layer may be a nanosheet extending along the first direction (x direction), and a thickness direction of the channel layer is in the second direction (y direction) intersecting (for example, perpendicular to) with the first direction. The gate width may be defined by the width of the channel layer in the first direction (x direction), and the gate length may be defined by the height of the channel layer in the vertical direction (z direction). The width of the channel layer in the lower device layer may be greater than the width of the channel layer in the upper device layer. The gate stack may be disposed on the periphery of the channel layer, so as to form the GAA configuration. In FIG. 34, gate stacks G₁, G₂, G₃ for respective device layers L₁, L₂, L₃ are shown. For example, as mentioned above, the gate stack G₁ may include a gate dielectric layer 1051 and a gate conductor layer 1053. The gate stack G₂ may include the gate dielectric layer 1051 and a gate conductor layer 1061. The gate stack G₃ may include the gate dielectric layer 1051 and the gate conductor layer 1053. An isolation layer 1045 may be disposed between adjacent device layers. It is noted that an isolation layer is not necessarily required between every two adjacent device layers.

The lower device layer may protrude in the first direction (x direction) relative to the upper device layer, so as to form the step structure. For example, the first device layer L₁ may protrude in the first direction relative to the second device layer L₂, so as to form the step S₁. The second device layer L₂ may protrude in the first direction relative to the third device layer L₃, so as to form the step S₂. The third device layer L₃ may form the step S₃. It is noted that a step may not necessarily require to be formed between every two adjacent device layers.

In addition, sub-steps may be formed on each step S₁, S₂ and S₃. The sub-steps may be formed at the two opposite ends of the corresponding steps in the second direction (y direction). For example, on the first step S₁, the gate stack G₁ may protrude in the second direction relative to the second source/drain layer 1009₁ (and the first source/drain layer 1005₁, the second source/drain layer 1009₁ and the first source/drain layer 1005₁ may be substantially aligned in the vertical direction on the side in the second direction) of the first device layer L₁, so as to form a sub-step SS₁. The first source/drain layer 1005₁ of the first device layer L₁ may protrude in the second direction relative to the second source/drain layer 1009₁ and the gate stack G₁ (herein, the gate stack G₁ is recessed in the second direction relative to the second source/drain layer 1009₁ to reduce the parasitic capacitance, as described above), so as to form a sub-step SS₄. Similarly, on the second step S₂, the gate stack G₂ may protrude in the second direction relative to the second source/drain layer 1009₂ (and the first source/drain layer 1005₂, the second source/drain layer 1009₂ and the first source/drain layer 1005₂ may be substantially aligned in the vertical direction on this side in the second direction) of the second device layer L₂, so as to form a sub-step SS₂. The first source/drain layer 1005₂ of the second device layer L₂ may protrude in the second direction relative to the second source/drain layer 1009₂ and the gate stack G₂ (herein the gate stack G₂ is recessed in the second direction relative to the second source/drain layer 1009₂ to reduce the parasitic capacitance, as described above), so as to form a sub-step SS₅. Similarly, on the third step S₃, the gate stack G₃ may protrude in the second direction relative to the second source/drain layer 1009₃ (and the first source/drain layer 1005₃, the second source/drain layer 1009₃ and the first source/drain layer 1005₃ may be substantially aligned in the vertical direction on this side in the second direction) of the third device layer L₃, so as to form a sub-step SS₃. The first source/drain layer 1005₃ of the third device layer L₃ may protrude in the second direction relative to the second source/drain layer 1009₃ and the gate stack G₃ (herein the gate stack G₃ is recessed in the second direction relative to the second source/drain layer 1009₃ to reduce the parasitic capacitance, as described above), so as to form a sub-step SS₆.

The contact portions to each device layer L₁, L₂ and L₃ may be located on the corresponding steps S₁, S₂ and S₃. The contact portions to each gate stack G₁, G₂ and G₃ may be located on the corresponding sub-steps SS₁, SS₂ and SS₃. The contact portions to the first source/drain layers 1005₁, 1005₂ and 1005₃ may be located on the corresponding sub-steps SS₄, SS₅ and SS₆.

The semiconductor apparatus according to embodiments of the present disclosure may be applied to various electronic devices. For example, an integrated circuit (IC) may be formed based on such semiconductor apparatus, and an electronic device may be constructed accordingly. Therefore, the present disclosure further provides an electronic device including the aforementioned semiconductor apparatus. The electronic device may further include a display screen that cooperates with the integrated circuit and a wireless transceiver that cooperates with the integrated circuit. Such electronic device may include a smart phone, a personal computer (PC), a tablet, an artificial intelligence device, a wearable device, or a mobile power supply.

According to embodiments of the present disclosure, a method of manufacturing a system on a chip (SoC) is further provided. Such method may include the methods described above. Specifically, various devices may be integrated on a chip, at least some of which are manufactured according to the methods of the present disclosure.

In the above description, the technical details such as patterning and etching of each layer are not described in detail. However, those skilled in the art should understand that various technical means may be employed to form a layer, a region, or the like having a desired shape. In addition, in order to form the same structure, those skilled in the art may also design a method that is not completely the same as the method described above. In addition, although the respective embodiments are described above separately, this does not mean that the measures in the respective embodiments cannot be advantageously used in combination.

The embodiments of the present disclosure have been described above. However, these examples are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should fall within the scope of the present disclosure.

1. A semiconductor apparatus, comprising:
a substrate;
a first semiconductor device and a second semiconductor device which are stacked on the substrate in a vertical direction, wherein each of the first semiconductor device and the second semiconductor device comprises a first source/drain layer, a channel layer and a second source/drain layer which are stacked in sequence in the vertical direction, and a gate stack surrounding a periphery of the channel layer,
wherein an end of the first source/drain layer, second source/drain layer and gate stack of the first semiconductor device in a first direction protrudes in the first direction relative to a corresponding end of the first source/drain layer, second source/drain layer and gate stack of the second semiconductor device in the first direction, so as to form a first step, and a second step is defined by the second semiconductor device,
wherein an end of respective first source/drain layer of the first semiconductor device and the second semiconductor device in a second direction intersecting with the first direction protrudes in the second direction relative to a corresponding end of respective second source/drain layer and gate stack of the first semiconductor device and the second semiconductor device in the second direction, so as to respectively form a first sub-step and a second sub-step, wherein the first sub-step is on the first step, and the second sub-step is on the second step,
wherein in each of the first semiconductor device and the second semiconductor device, another end of the gate stack in the second direction, which is opposite to the end of the gate stack in the second direction, protrudes in the second direction relative to another end of the second source/drain layer in the second direction, which is opposite to the end of the second source/drain layer in the second direction.

2. The semiconductor apparatus of claim 1, further comprising:
a dielectric connected to the another end of respective first source/drain layer and second source/drain layer of the first semiconductor device and the second semiconductor device in the second direction, wherein the dielectric respectively sandwiches respective gate stack of the first semiconductor device and the second semiconductor device in the vertical direction.

3. The semiconductor apparatus of claim 1, further comprising:
a first contact portion, a second contact portion and a third contact portion that are arranged in the second direction;
a fourth contact portion, a fifth contact portion and a sixth contact portion that are arranged in the second direction,
wherein the first contact portion, the second contact portion and the third contact portion are located above the first step, and the fourth contact portion, the fifth contact portion and the sixth contact portion are located above the second step,
wherein the first contact portion is located above the first sub-step and lands on the first source/drain layer of the first semiconductor device, the second contact portion lands on the second source/drain layer of the first semiconductor device, and the third contact portion is close to the another end of the gate stack of the first semiconductor device in the second direction and lands on the gate stack of the first semiconductor device,
wherein the fourth contact portion is located above the second sub-step and lands on the first source/drain layer of the second semiconductor device, the fifth contact portion lands on the second source/drain layer of the second semiconductor device, and the sixth contact portion is close to the another end of the gate stack of the second semiconductor device in the second direction and lands on the gate stack of the second semiconductor device.

4. The semiconductor apparatus of claim 3, wherein
the first contact portion, the second contact portion and the third contact portion are arranged in a straight line in the second direction, and the fourth contact portion, the fifth contact portion and the sixth contact portion are arranged in a straight line in the second direction; or
the first contact portion, the second contact portion and the third contact portion are arranged in a zigzag shape in the second direction, and the fourth contact portion, the fifth contact portion and the sixth contact portion are arranged in a zigzag shape in the second direction.

5. The semiconductor apparatus of claim 1, further comprising:
an isolation layer located between the first semiconductor device and the second semiconductor device in the vertical direction.

6. The semiconductor apparatus of claim 5, wherein the isolation layer is located between the second source/drain layer of the first semiconductor device and the first source/drain layer of the second semiconductor device and achieves electrical isolation.

7. The semiconductor apparatus of claim 5, wherein the isolation layer substantially completely overlaps with the first source/drain layer of the second semiconductor device in a top view.

8. The semiconductor apparatus of claim 5, wherein a thickness of the isolation layer in the vertical direction is less than a height of the channel layer in the vertical direction.

9. The semiconductor apparatus of claim 1, wherein the another end of the first source/drain layer and second source/drain layer of the first semiconductor device in the second direction is substantially aligned in the vertical direction with the another end of the first source/drain layer and second source/drain layer of the second semiconductor device in the second direction.

10. The semiconductor apparatus of claim 1, wherein another end of the first source/drain layer and second source/drain layer of the first semiconductor device in the first direction, which is opposite to the end of the first source/drain layer and second source/drain layer of the first semiconductor device in the first direction, is substantially aligned in the vertical direction with another end of the first source/drain layer and second source/drain layer of the second semiconductor device in the first direction, which is opposite to the end of the first source/drain layer and second source/drain layer of the second semiconductor device in the first direction.

11. The semiconductor apparatus of claim 1, wherein
in the first semiconductor device, the end of the gate stack in the first direction and another end of the gate stack in the first direction opposite to the end of the gate stack are substantially aligned in the vertical direction with a corresponding end of the second source/drain layer,
in the second semiconductor device, the end of the gate stack in the first direction and another end of the gate stack in the first direction opposite to the end of the gate stack are substantially aligned in the vertical direction with a corresponding end of the second source/drain layer.

12. The semiconductor apparatus of claim 1, wherein
the end of the gate stack of the first semiconductor device in the second direction is recessed in the second direction relative to the end of the second source/drain layer of the first semiconductor device in the second direction,
the end of the gate stack of the second semiconductor device in the second direction is recessed in the second direction relative to the end of the second source/drain layer of the second semiconductor device in the second direction.

13. The semiconductor apparatus of claim 1, wherein
in the first semiconductor device, the gate stack has a substantially same first width on two opposite sides of the channel layer in the first direction, and the first width is measured in the first direction,
in the second semiconductor device, the gate stack has a substantially same second width on two opposite sides of the channel layer in the first direction, and the second width is measured in the first direction.

14. The semiconductor apparatus of claim 13, wherein the first width is substantially equal to the second width.

15. The semiconductor apparatus of claim 1, wherein the channel layer has a first dimension in the first direction, a second dimension in the second direction and a third dimension in the vertical direction, wherein the second dimension is less than the first dimension and the third dimension, so that the channel layer is in a form of a nanosheet extending along the first direction, and a thickness of the nanosheet is formed by the second dimension.

16. The semiconductor apparatus of claim 15, wherein the first dimension of the channel layer of the first semiconductor device is greater than the first dimension of the channel layer of the second semiconductor device.

17. The semiconductor apparatus of claim 16, wherein the first dimension of the channel layer of the first semiconductor device is greater than the first dimension of the channel layer of the second semiconductor device by about: a size of the first step in the first direction.

18. The semiconductor apparatus of claim 15, wherein the channel layer is in a shape of C in a cross-section perpendicular to the first direction.

19. The semiconductor apparatus of claim 18, wherein an opening of the shape of C of the first semiconductor device faces away from the first sub-step, and an opening of the shape of C of the second semiconductor device faces away from the second sub-step.

20. The semiconductor apparatus of claim 1, further comprising:
a third semiconductor device stacked on the second semiconductor device in the vertical direction, wherein the third semiconductor device comprises a first source/drain layer, a channel layer and a second source/drain layer which are stacked in sequence in the vertical direction, and a gate stack surrounding a periphery of the channel layer of the third semiconductor device,
wherein an end of the first source/drain layer, second source/drain layer and gate stack of the second semiconductor device in the first direction protrudes in the first direction relative to an end of the first source/drain layer, second source/drain layer and gate stack of the third semiconductor device in the first direction, so as to form the second step,
wherein the second sub-step is on the second step.

21. The semiconductor apparatus of claim 20, wherein a third step is defined by the third semiconductor device,
wherein an end of the first source/drain layer of the third semiconductor device in the second direction protrudes in the second direction relative to a corresponding end of the second source/drain layer and gate stack of the third semiconductor device in the second direction, so as form a third sub-step, wherein the third sub-step is on the third step,
wherein in the third semiconductor device, another end of the gate stack in the second direction, which is opposite to the end of the gate stack in the second direction, protrudes in the second direction relative to another end of the second source/drain layer in the second direction, which is opposite to the end of the second source/drain layer in the second direction.

22. The semiconductor apparatus of claim 1, wherein the second semiconductor device is a device on the top, and the second step is formed by the first source/drain layer, second source/drain layer and gate stack of the second semiconductor device.

23. The semiconductor apparatus of claim 1, wherein a thickness of the first source/drain layer and second source/drain layer of the first semiconductor device in the vertical direction is greater than a thickness of the first source/drain layer and second source/drain layer of the second semiconductor device in the vertical direction.

24. The semiconductor apparatus of claim 1, wherein a height of the channel layer of the first semiconductor device in the vertical direction is different from a height of the channel layer of the second semiconductor device in the vertical direction.

25. A method of manufacturing a semiconductor apparatus, comprising:
disposing a stack comprising n device layers on a substrate, wherein each device layer comprises a first source/drain layer, a channel defining layer and a second source/drain layer which are stacked in sequence, and n is an integer greater than or equal to 2;
forming a step structure on a side of the stack in a first direction, wherein a step is formed by a lower device layer relative to an upper device layer;
recessing, on two opposite sides in the first direction, the channel defining layer in each device layer in the first direction relative to the first source/drain layer and second source/drain layer in each device layer, so as to obtain a first gap, and forming a first sacrificial gate in the first gap;
recessing, on a side of the stack in a second direction intersecting with the first direction, the channel defining layer in each device layer in the second direction relative to the first source/drain layer and second source/drain layer in each device layer, so as to obtain a second gap;
forming a channel layer on a sidewall of a recess of each channel defining layer;
forming a second sacrificial gate in a space of the second gap after forming the channel layer;
forming, on the side of the stack in the second direction, a step structure in each device layer: a sub-step is formed by each second sacrificial gate relative to the second source/drain layer in a corresponding device layer;
removing, on another side of the stack opposite to the side of the stack in the second direction, the channel defining layer by selectively etching, so as to obtain a third gap, and forming a third sacrificial gate in the third gap;
forming, on the another side of the stack in the second direction, a step structure in each device layer: a sub-step is formed by the first source/drain layer relative to the second source/drain layer and channel defining layer in a same device layer, and the sub-step is on the step formed in the corresponding device layer; and
replacing the first sacrificial gate, the second sacrificial gate and the third sacrificial gate by a gate stack.

26. The method of claim 25, wherein the stack is disposed by epitaxial growth.

27. The method of claim 25, wherein each device layer further comprises an isolation defining layer, and the first source/drain layer, the channel defining layer and the second source/drain layer are disposed on the isolation defining layer,
wherein the method further comprises: removing, on the another side of the stack in the second direction, the isolation defining layer by selectively etching to obtain a gap, and filling the gap with an isolation material to form an isolation layer.

28. The method of claim 27, wherein a thickness of the isolation defining layer in a vertical direction is less than a thickness of the channel defining layer in the vertical direction.

29. The method of claim 25, wherein forming the step structure comprises:
(a) forming, on the stack, a strip cushion layer extending along the second direction;
(b) forming, on the stack, a strip photoresist extending along the second direction, wherein an edge portion of the photoresist in the first direction overlaps with the cushion layer;
(c) etching the stack by a certain depth by using the cushion layer and the photoresist as an etching mask;
(d) trimming the photoresist to reduce a width of the photoresist in the first direction;
(e) etching the stack by a certain depth by using the cushion layer and a trimmed photoresist as an etching mask; and
(f) repeating (d) and (e), until the step structure is formed.

30. The method of claim 29, wherein the depth of etching in (c) is D₁+D_{STI}, and the depth of each etching is D₂, . . . , Dₙ in sequence when (e) is repeated in (f), wherein Dᵢ represents a thickness of an i^{th} device layer from bottom to top, the thickness is in a vertical direction, i is an integer from 1 to n, and D_{STI} represents a depth of a shallow trench isolation to be formed.

31. The method of claim 29, wherein the trimmed photoresist is not separated from the cushion layer in the first direction at least before a last trimming.

32. The method of claim 31, wherein the last trimming comprises removing the photoresist.

33. The method of claim 29, wherein
a width of the cushion layer in the first direction is W, and a height of the cushion layer in a vertical direction is H, and (H+W)>(W₁-W₁₁) is satisfied, wherein W₁ represents a width of a first device layer from bottom to top after forming the step structure, and Wₙ₋₁ represents a width of an (n−1)^{th} device layer from bottom to top after forming the step structure, and wherein the width of the first device layer and the width of the (n−1)^{th} device layer are in the first direction,
a thickness of the photoresist in the vertical direction is greater than (H+W).

34. The method of claim 25, further comprising:
etching, through the second gap, the channel defining layer, the first source/drain layer and the second source/drain layer by a certain depth, so as to increase the second gap,
wherein a thickness of the formed channel layer is substantially equal to the depth being etched.

35. The method of claim 25, wherein forming the step structure in each device layer comprising:
removing an end region of an exposed portion of the second source/drain layer of each device layer in the second direction by selectively etching, and removing a portion of the third sacrificial gate exposed due to a removal of the end region by selectively etching, so as to expose a lower first source/drain layer.

36. An electronic device comprising the semiconductor apparatus of claim 1.

37. The electronic device of claim 36, wherein the electronic device comprises a smart phone, a personal computer, a tablet, an artificial intelligence device, a wearable device, or a mobile power supply.
